(19) United States
(12) Patent Application Publication
(10) Pub. No.: US 2013/0065183 A1
(43) Pub. Date: Mar. 14, 2013

(54) PATTERNING PROCESS AND RESIST COMPOSITION

(71) Applicants: Tomohiro Kobayashi, Joetsu-shi (JP); Jun Hatakeyama, Joetsu-shi (JP); Masashi Iio, Joestsu-shi (JP); Yuuki Suka, Joetsu-shi (JP); Koji Hasegawa, Joetsu-shi (JP); Yuji Harada, Joetsu-shi (JP)

(72) Inventors: Tomohiro Kobayashi, Joetsu-shi (JP); Jun Hatakeyama, Joetsu-shi (JP); Masashi Iio, Joestsu-shi (JP); Yuuki Suka, Joetsu-shi (JP); Koji Hasegawa, Joetsu-shi (JP); Yuji Harada, Joetsu-shi (JP)

(73) Assignee: SHIN-ETSU CHEMICAL CO., LTD., Tokyo (JP)

(21) Appl. No.: 13/606,297

(22) Filed: Sep. 7, 2012

(30) Foreign Application Priority Data
Sep. 9, 2011 (JP) 2011-196667

(51) Int. Cl. G03F 7/004; G03F 7/20

(52) U.S. Cl. 430/285.1; 430/325; 430/270.1

(57) ABSTRACT

A resist composition is provided comprising a polymer comprising recurring units having a protected hydroxyl group, a photoacid generator, an organic solvent, and a hydroxyl-free polymeric additive comprising fluorinated recurring units. A negative pattern is formed by coating the resist composition, prebaking to form a resist film, exposing, baking, and developing the exposed film in an organic solvent-based developer to selectively dissolve the unexposed region of resist film.

### CROSS-REFERENCE TO RELATED APPLICATION

This non-provisional application claims priority under 35 U.S.C. §119(a) on Patent Application No. 2011-196667 filed in Japan on Sep. 9, 2011, the entire contents of which are hereby incorporated by reference.

### TECHNICAL FIELD

This invention relates to a specific resist composition, and a pattern forming process involving forming a resist film from the composition, exposure, baking to induce deprotection reaction under the catalysis of acid generated by a photoacid generator, and development in an organic solvent to form a negative tone pattern in which the unexposed region is dissolved and the exposed region is not dissolved.

### BACKGROUND ART

In the recent drive for higher integration and operating speeds in LSI devices, the pattern rule is made drastically finer. The photolithography which is currently on widespread use in the art is approaching the essential limit of resolution determined by the wavelength of a light source. As the light source used in the lithography for resist pattern formation, g-line (436 nm) or i-line (365 nm) from a mercury lamp was widely used in 1980's. Reducing the wavelength of exposure light was believed effective as the means for further reducing the feature size. For the mass production process of 64 MB dynamic random access memories (DRAM, processing feature size 0.25 μm or less) in 1990's and later ones, the exposure light source of i-line (365 nm) was replaced by a KrF excimer laser having a shorter wavelength of 248 nm. However, for the fabrication of DRAM with a degree of integration of 256 MB and 1 GB or more requiring a finer patterning technology (processing feature size 0.2 μm or less), a shorter wavelength light source was required. Over a decade, photolithography using ArF excimer laser light (193 nm) has been under active investigation. It was expected at the initial that the ArF lithography would be applied to the fabrication of 180-nm node devices. However, the KrF excimer lithography survived to the mass-scale fabrication of 130-nm node devices. So, the full application of ArF lithography started from the 90-nm node. The ArF lithography combined with a lens having an increased numerical aperture (NA) of 0.9 is considered to comply with 65-nm node devices. For the next 45-nm node devices which required an advancement to reduce the wavelength of exposure light, the F₂ lithography of 157 nm wavelength became a candidate. However, for the reasons that the projection lens uses a large amount of expensive CaF₂ single crystal, the scanner thus becomes expensive, hard pellicles are introduced due to the extremely low durability of soft pellicles, the optical system must be accordingly altered, and the etch resistance of resist is low; the development of F₂ lithography was stopped and instead, the ArF immersion lithography was introduced.

In the ArF immersion lithography, the space between the projection lens and the wafer is filled with water having a refractive index of 1.44. The partial fill system is compliant with high-speed scanning and when combined with a lens having a NA of 1.3, enables mass production of 45-nm node devices.

One candidate for the 32-nm node lithography is lithography using extreme ultraviolet (EUV) radiation with wavelength 13.5 nm. The EUV lithography has many accumulative problems to be overcome, including increased laser output, increased sensitivity, increased resolution and minimized edge roughness (LER, LWR) of resist film, defect-free MoSi laminate mask, reduced aberration of reflection mirror, and the like.

Another candidate for the 32-nm node lithography is high refractive index liquid immersion lithography. The development of this technology was stopped because LUAG, a high refractive index lens candidate had a low transmittance and the refractive index of liquid did not reach the goal of 1.8.

The process that now draws attention under the above-discussed circumstances is a double patterning process involving a first set of exposure and development to form a first pattern and a second set of exposure and development to form a pattern between the first pattern features. A number of double patterning processes are proposed. One exemplary process involves a first set of exposure and development to form a photoresist pattern having lines and spaces at intervals of 1:3, processing the underlying layer of hard mask by dry etching, applying another layer of hard mask thereon, a second set of exposure and development of a photoresist film to form a line pattern in the spaces of the first exposure, and processing the hard mask by dry etching, thereby forming a line-and-space pattern at a half pitch of the first pattern. An alternative process involves a first set of exposure and development to form a photoresist pattern having spaces and lines at intervals of 1:3, processing the underlying layer of hard mask by dry etching, applying a photoresist layer thereon, a second set of exposure and development to form a second space pattern on the remaining hard mask portion, and processing the hard mask by dry etching. In either process, the hard mask is processed by two dry etchings.

As compared with the line pattern, the hole pattern is difficult to reduce the feature size. In order for the prior art method to form fine holes, an attempt is made to form fine holes by under-exposure of a positive resist film combined with a hole pattern mask. This, however, results in the exposure margin being extremely narrowed. It is then proposed to form holes of greater size, followed by thermal flow or RELACS® method to shrink the holes as developed. With the hole shrinking method, the hole size can be shrunk, but the pitch cannot be narrowed.

It is then proposed in Non-Patent Document 1 that a pattern of X-direction lines is formed in a positive resist film using dipole illumination, the resist pattern is cured, another resist material is coated thereon, and a pattern of Y-direction lines is formed in the other resist film using dipole illumination, leaving a grid line pattern, spaces of which provide a hole pattern. Although a hole pattern can be formed at a wide margin by combining X and Y lines and using dipole illumination featuring a high contrast, it is difficult to etch vertically staged line patterns at a high dimensional accuracy. It is proposed in Non-Patent Document 2 to form a hole pattern by exposure of a negative resist film through a Levenson phase shift mask of X-direction lines combined with a Levenson phase shift mask of Y-direction lines. However, the crosslinking negative resist film has the drawback that the resolving power is low as compared with the positive resist film, because the maximum resolution of ultrafine holes is determined by the bridge margin.

A hole pattern resulting from a combination of two exposures of X- and Y-direction lines and subsequent image reversal into a negative pattern can be formed using a high-contrast line pattern of light. This enables to open holes having a narrow pitch and fine size as compared with the prior art.

Non-Patent Document 3 reports three methods for forming hole patterns via image reversal. The three methods are: method (1) involving subjecting a positive resist composition to two double-dipole exposures of X and Y lines to form a dot pattern, depositing a SiO₂ film thereon by LPCVD, and effecting O₂-RIE for reversal of dots into holes; method (2) involving forming a dot pattern by the same steps as in (1), but using a resist composition designed to turn alkali-soluble and solvent-insoluble upon heating, coating a phenol-base overcoat film thereon, effecting alkaline development for image reversal to form a hole pattern; and method (3) involving double dipole exposure of a positive resist composition and organic solvent development for image reversal to form holes.

The organic solvent development to form a negative pattern is a traditional technique. A resist composition comprising cyclized rubber is developed using an alkene such as xylene as the developer. An early chemically amplified resist composition comprising poly(tert-butoxycarbonyloxystyrene) is developed with anisole as the developer to form a negative pattern.

Recently a highlight is put on the organic solvent development again. It would be desirable if a very fine trench or hole pattern, which is not achievable with the positive tone, is resolvable through negative tone exposure/development. To this end, a positive resist composition featuring a high resolution is subjected to organic solvent development to form a negative pattern. An attempt to double a resolution by combining two developments, alkaline development and organic solvent development is under study.

As the ArF resist composition for negative tone development with organic solvent, positive ArF resist compositions of the prior art design may be used. Such pattern forming processes are described in Patent Documents 1 to 6.

Also a fine size negative pattern can be formed by combining the ArF immersion lithography using water medium with organic solvent development. In the immersion lithography where a resist film is exposed while water is present on the resist film, the acid generated within the resist film and the basic compound previously added to the resist material can be, in part, leached into the water layer. Such leach-out may cause pattern profile changes and pattern collapse. It is also pointed out that water droplets remaining on the resist film, though in a minute volume, can penetrate into the resist film to generate defects.

One proposal for mitigating the above drawbacks of the ArF immersion lithography is provision of a protective film of fluorinated material between the resist film and water. Among others, a protective film of the type which is soluble in alkaline developer as disclosed in Patent Document 7 is epoch-making in that it eliminates a need for a special stripping unit because it can be stripped off at the same time as the development of a photoresist film.

Patent Document 8 proposes the addition of an alkali-soluble hydrophobic compound to resist material as means for further simplifying the process. This means is advantageous over the use of a resist protective film because the steps of forming and removing the protective film are unnecessary.

Although the combination of the ArF immersion lithography with organic solvent development has opened a window toward formation of a fine size negative pattern, there still remains a concern about the problem of pattern collapse inherent to negative patterns. Since the negative patterning is such that the exposed region becomes insoluble in developer, the pattern tends to assume a negative profile having an increased top size and is thus prone to collapse. The main application of negative patterning is formation of trench and hole patterns which are advantageous from the aspect of optical contrast. Since these patterns entail more remaining resist film, there is little likelihood of pattern collapse. However, since the circuit design of actual devices is so complex that a mixture of fine line patterns is often present even in a device layer including many trenches or holes, the problem of pattern collapse is serious.

In general, the negative development in organic solvent provides a low dissolution contrast, as compared with the positive development in alkaline aqueous solution. In the case of alkaline developer, the alkali dissolution rate differs more than 1,000 times between unexposed and exposed regions, whereas the difference is only about 10 times in the case of organic solvent development. In the case of negative development, a shortage of dissolution contrast can lead to a more negative profile and substantially insolubilized surface, which adds to the likelihood of pattern collapse.

### CITATION LIST

Patent Document 1: JP-A 2008-281974
Patent Document 2: JP-A 2008-281975
Patent Document 3: JP-A 2008-281980
Patent Document 4: JP-A 2009-053657
Patent Document 5: JP-A 2009-025707
Patent Document 6: JP-A 2009-025723
Patent Document 7: JP-A 2005-264131
Patent Document 8: JP-A 2006-048029
Non-Patent Document 1: Proc. SPIE Vol. 5377, p. 255 (2004)
Non-Patent Document 2: IEEE IEDM Tech. Digest 61 (1996)
Non-Patent Document 3: Proc. SPIE Vol. 7274, p. 72740N (2009)

### DISCLOSURE OF INVENTION

An object of the invention is to provide a resist composition which has a sufficient receding contact angle to enable immersion lithography without a need for protective film, and exhibits a high resolution and pattern collapse resistance on organic solvent development. Another object is to provide a process of forming a negative pattern by organic solvent development of the resist composition.

The inventors have found that a resist composition comprising a polymer comprising an acid labile unit of specific structure, a photoacid generator, an organic solvent, and a fluorinated polymeric additive of specific structure has a high receding contact angle, exhibits a high resolution and satisfactory pattern profile on organic solvent development, and is improved in pattern collapse resistance.

Accordingly, in one aspect, the invention provides a pattern forming process comprising the steps of applying a resist composition onto a substrate; prebaking the composition to form a resist film; exposing the resist film to high-energy radiation; baking; and developing the exposed film in an organic solvent-based developer to selectively dissolve the unexposed region of resist film to form a negative pattern; the resist composition comprising (A) a polymer comprising recurring units of the structure having a hydroxyl group protected with an acid labile group, (B) a photoacid generator, (C) an organic solvent, and (D) a polymeric additive comprising recurring units having at least one fluorine atom, the polymeric additive being free of hydroxyl.

In a preferred embodiment, the polymer comprising recurring units of the structure having a hydroxyl group protected with an acid labile group comprises recurring units having the general formula (1).

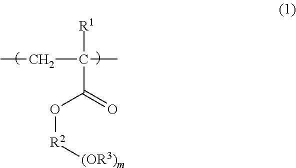

Herein R¹ is hydrogen or methyl, R² is a straight, branched or cyclic C₂-C₁₆ aliphatic hydrocarbon group having a valence of 2 to 5, which may contain an ether or ester bond, R³ is an acid labile group, and m is an integer of 1 to 4.

More preferably, the acid labile group R³ in recurring unit (1) has the general formula (2).

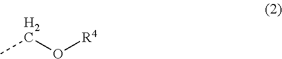

Herein the broken line denotes a valence bond and R⁴ is a monovalent, straight, branched or cyclic C₁-C₁₅ hydrocarbon group.

In a preferred embodiment, the polymeric additive (D) comprising recurring units having at least one fluorine atom comprises recurring units of one or more type having the general formula (3).

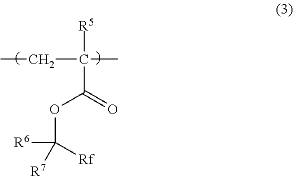

Herein R⁵ is hydrogen, methyl or trifluoromethyl, R⁶ and R⁷ are each independently hydrogen or a straight, branched or cyclic C₁-C₁₅ alkyl group, or R⁶ and R⁷ may bond together to form a ring with the carbon atom to which they are attached, and Rf is a straight or branched C₁-C₁₅ alkyl group in which at least one hydrogen atom is substituted by a fluorine atom.

In a preferred embodiment, the developer comprises at least one organic solvent selected from the group consisting of 2-octanone, 2-nonanone, 2-heptanone, 3-heptanone, 4-heptanone, 2-hexanone, 3-hexanone, diisobutyl ketone, 2-methylcyclohexanone, 3-methylcyclohexanone, 4-methylcyclohexanone, acetophenone, 2′-methylacetophenone, 4′-methylacetophenone, propyl acetate, butyl acetate, isobutyl acetate, amyl acetate, isoamyl acetate, butenyl acetate, phenyl acetate, propyl formate, butyl formate, isobutyl formate, amyl formate, isoamyl formate, methyl valerate, methyl pentenoate, methyl crotonate, ethyl crotonate, methyl lactate, ethyl lactate, propyl lactate, butyl lactate, isobutyl lactate, amyl lactate, isoamyl lactate, methyl 2-hydroxyisobutyrate, ethyl 2-hydroxyisobutyrate, methyl benzoate, ethyl benzoate, benzyl acetate, methyl phenylacetate, benzyl formate, phenylethyl formate, methyl 3-phenylpropionate, benzyl propionate, ethyl phenylacetate, and 2-phenylethyl acetate, in a concentration of at least 60% by weight of the developer.

In a preferred embodiment, the step of exposing the resist film to high-energy radiation includes ArF excimer laser immersion lithography of 193 nm wavelength or EUV lithography of 13.5 nm wavelength.

In another aspect, the invention provides a resist composition comprising (A) a polymer comprising recurring units of the structure having a hydroxyl group protected with an acid labile group, (B) a photoacid generator, (C) an organic solvent, and (D) a polymeric additive comprising recurring units having at least one fluorine atom, the polymeric additive being free of hydroxyl, the polymeric additive being present in an amount of 1% to 30% by weight based on the total amount of all polymers.

In a preferred embodiment, the polymer comprising recurring units of the structure having a hydroxyl group protected with an acid labile group comprises recurring units having above formula (1). Preferably the acid labile group R³ in recurring unit (1) has above formula (2).

In a preferred embodiment, the polymeric additive (D) comprising recurring units having at least one fluorine atom comprises recurring units of one or more type having above formula (3).

### Advantageous Effects of Invention

The resist composition comprising a polymer comprising an acid labile unit of specific structure, a photoacid generator, an organic solvent, and a fluorinated polymeric additive of specific structure forms a resist film having a sufficient receding contact angle to enable immersion lithography without a need for protective film. When combined with organic solvent development, the resist composition exhibits a high resolution, for example, a wide depth of focus for forming fine trench patterns and hole patterns, perpendicular line pattern sidewalls, and improved pattern collapse resistance.

### BRIEF DESCRIPTION OF DRAWINGS

FIG. 1 is a cross-sectional view of a patterning process according one embodiment of the invention. FIG. 1A shows a photoresist film disposed on a substrate, FIG. 1B shows the resist film being exposed, and FIG. 1C shows the resist film being developed in an organic solvent.

FIG. 2 is an optical image of X-direction lines having a pitch of 90 nm and a line size of 45 nm printed under conditions: ArF excimer laser of wavelength 193 nm, NA 1.3 lens, dipole illumination, 6% halftone phase shift mask, and s-polarization.

FIG. 3 is an optical image of Y-direction lines like FIG. 2.

FIG. 4 shows a contrast image obtained by overlaying the optical image of X-direction lines in FIG. 2 with the optical image of Y-direction lines in FIG. 3.

FIG. 5 illustrates a mask bearing a lattice-like pattern.

FIG. 6 is an optical image of a lattice-like line pattern having a pitch of 90 nm and a line width of 30 nm printed under conditions: NA 1.3 lens, cross-pole illumination, 6% halftone phase shift mask, and azimuthally polarized illumination.

FIG. 7 illustrates a mask bearing a dot pattern of square dots having a pitch of 90 nm and a side width of 60 nm.

FIG. 8 is an optical image resulting from the mask of FIG. 7, printed under conditions: NA 1.3 lens, cross-pole illumination, 6% halftone phase shift mask, and azimuthally polarized illumination, showing its contrast.

FIG. 9 illustrates a mask bearing a lattice-like pattern having a pitch of 90 nm and a line width of 20 nm on which thick crisscross or intersecting line segments are disposed where dots are to be formed.

FIG. 10 is an optical image resulting from the mask of FIG. 9, printed under conditions: NA 1.3 lens, cross-pole illumination, 6% halftone phase shift mask, and azimuthally polarized illumination, showing its contrast.

FIG. 11 illustrates a mask bearing a lattice-like pattern having a pitch of 90 nm and a line width of 15 nm on which thick dots are disposed where dots are to be formed.

FIG. 12 is an optical image resulting from the mask of FIG. 11, printed under conditions: NA 1.3 lens, cross-pole illumination, 6% halftone phase shift mask, and azimuthally polarized illumination, showing its contrast.

FIG. 13 illustrates a mask without a lattice-like pattern.

FIG. 14 is an optical image resulting from the mask of FIG. 13, printed under conditions: NA 1.3 lens, cross-pole illumination, 6% halftone phase shift mask, and azimuthally polarized illumination, showing its contrast.

FIG. 15 illustrates an aperture configuration in an exposure tool of dipole illumination for enhancing the contrast of X-direction lines.

FIG. 16 illustrates an aperture configuration in an exposure tool of dipole illumination for enhancing the contrast of Y-direction lines.

FIG. 17 illustrates an aperture configuration in an exposure tool of cross-pole illumination for enhancing the contrast of both X and Y-direction lines.

### DESCRIPTION OF EMBODIMENTS

The terms “a” and “an” herein do not denote a limitation of quantity, but rather denote the presence of at least one of the referenced item. As used herein, the notation (Cₙ-Cₘ) means a group containing from n to m carbon atoms per group. As used herein, the term “film” is used interchangeably with “coating” or “layer.” The term “processable layer” is interchangeable with patternable layer and refers to a layer that can be processed such as by etching to form a pattern therein.

For a certain compound represented by a chemical formula, there can exist enantiomers or diastereomers. A single planar or stereoisomeric formula collectively represents all such stereoisomers. Such stereoisomers may be used alone or in admixture. In the chemical formula, the broken line denotes a valence bond.

The abbreviations and acronyms have the following meaning.

Mw: weight average molecular weight

Mn: number average molecular weight

Mw/Mn: molecular weight distribution or dispersity

GPC: gel permeation chromatography

PEB: post-exposure bake

PAG: photoacid generator

### Resist Composition

One embodiment of the invention is a resist composition comprising (A) a polymer comprising recurring units having a hydroxyl group protected with an acid labile group, (B) a photoacid generator, (C) an organic solvent, and (D) a hydroxyl-free polymeric additive comprising recurring units having at least one fluorine atom.

Component (A) is a polymer comprising recurring units of the structure having a hydroxyl group protected with an acid labile group, which serves as a base resin. The recurring unit having a hydroxyl group protected with an acid labile group is not particularly limited as long as the unit has one or more structure having a hydroxyl group protected with a protective group wherein the protective group is decomposable under the action of acid to generate a hydroxyl group. The preferred recurring unit has a structure of the general formula (1).

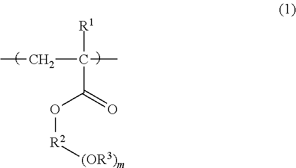

Herein R¹ is hydrogen or methyl, R² is a straight, branched or cyclic C₂-C₁₆ aliphatic hydrocarbon group having a valence of 2 to 5, which may contain an ether bond (—O—) or ester bond (—COO—), R³ is an acid labile group, and m is an integer of 1 to 4.

Illustrative, non-limiting examples of the recurring unit having formula (1) are given below.

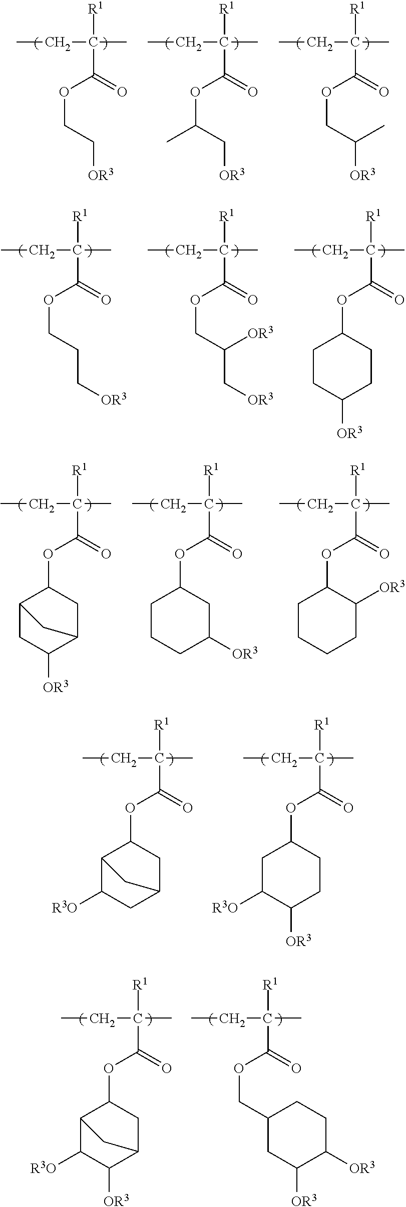

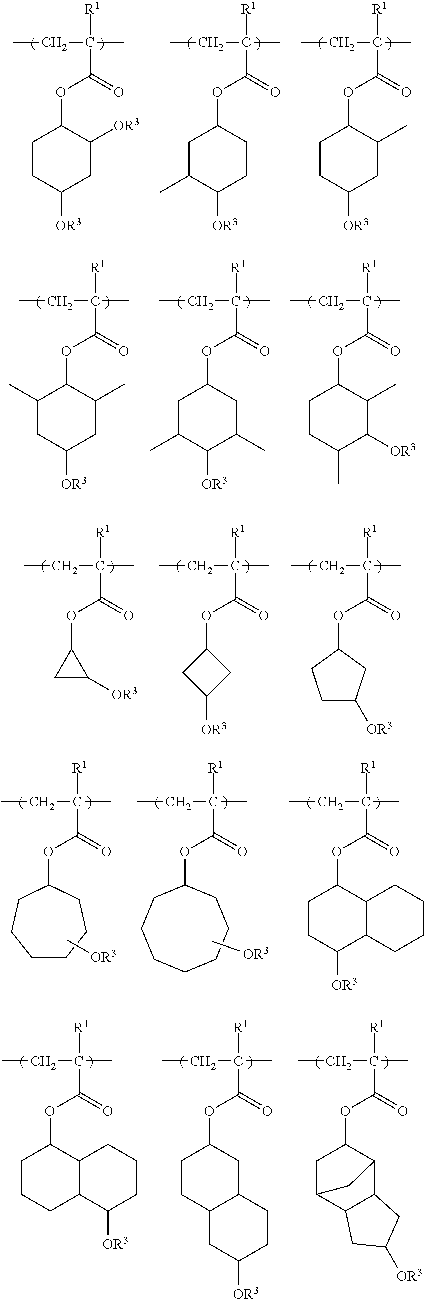

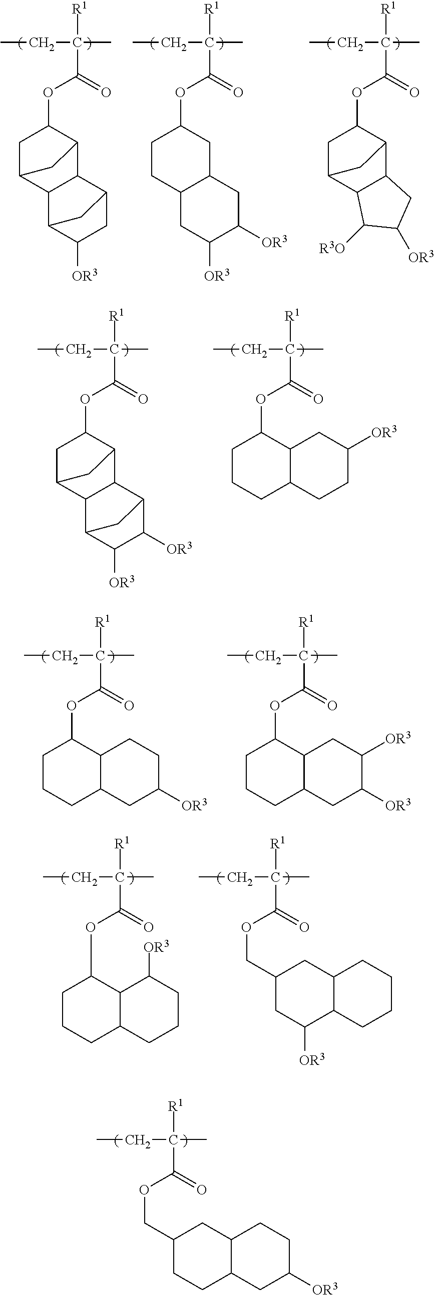

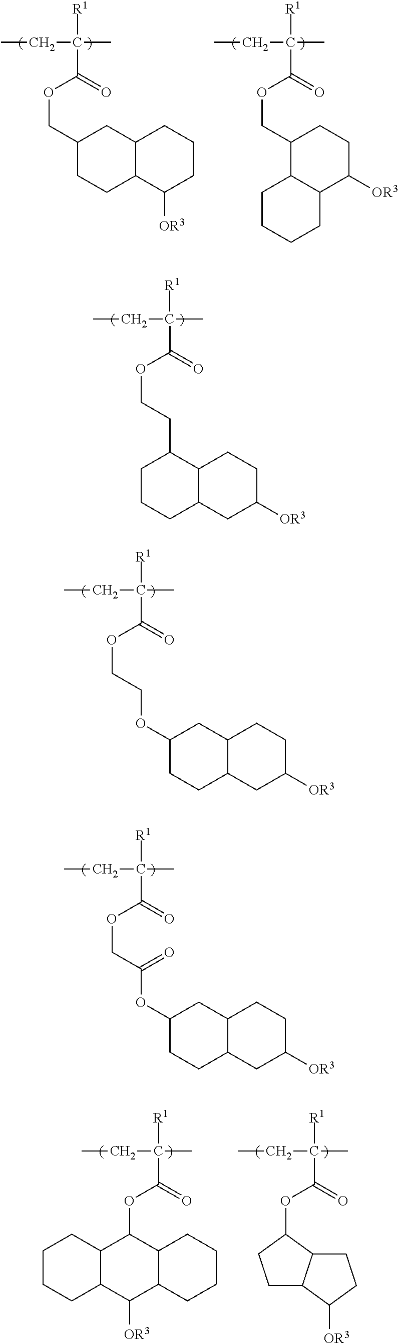

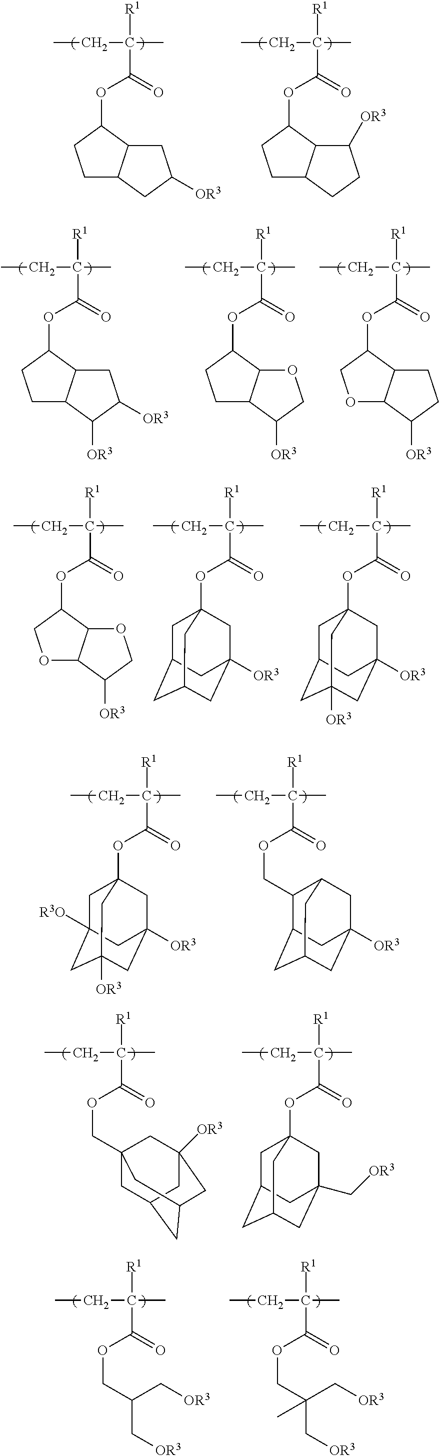

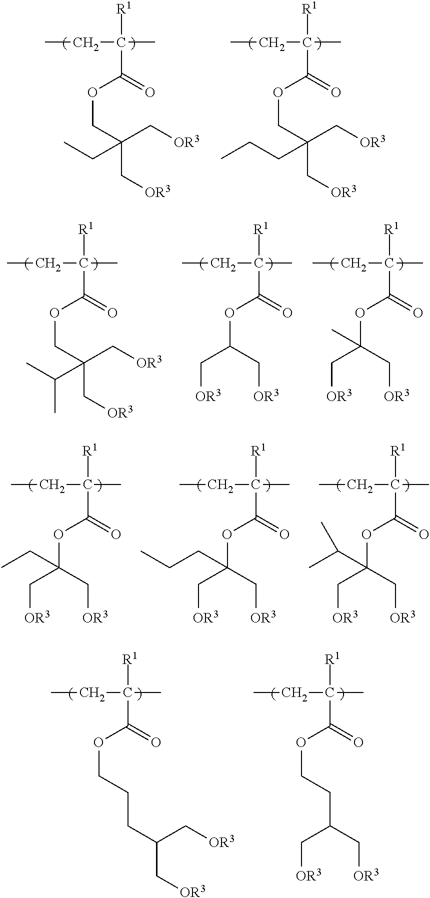

It is noted R¹ and R³ are as defined above.

In general, the recurring unit having a hydroxyl group protected with an acid labile group generates a hydroxyl group having a low acidity via deprotection. The recurring unit capable of generating hydroxyl group has a very low alkaline dissolution rate as compared with the recurring unit capable of generating a carboxyl group via deprotection reaction, and is thus believed incompatible with positive development using alkaline aqueous solution as developer. When applied to negative tone image formation using organic solvent as developer, however, the recurring unit capable of generating hydroxyl group is characterized by a high dissolution contrast between the unexposed region of promoted dissolution and the exposed region of inhibited dissolution. Accordingly the recurring unit capable of generating hydroxyl group enhances the resolution of a fine size pattern and contributes to an improvement in perpendicularity of pattern sidewalls.

The acid labile group R³ in formula (1) is not particularly limited as long as it is deprotected under the action of acid to generate a hydroxyl group. The acid labile groups include acetal structure, ketal structure and alkoxycarbonyl groups. Exemplary acid labile groups include the following structures.

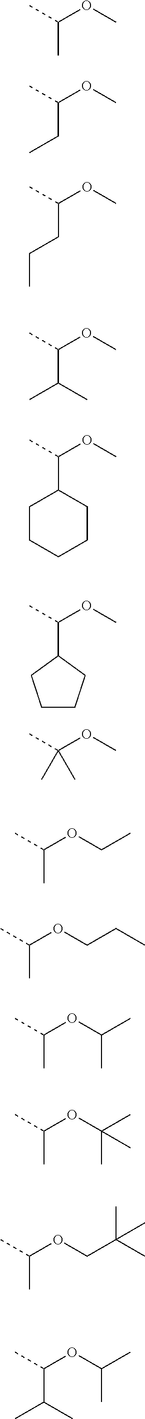

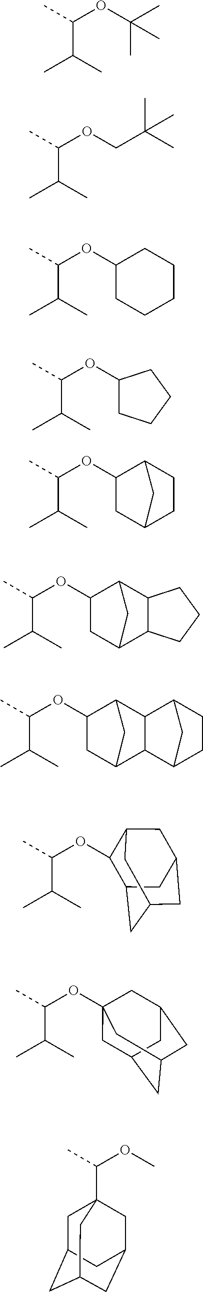

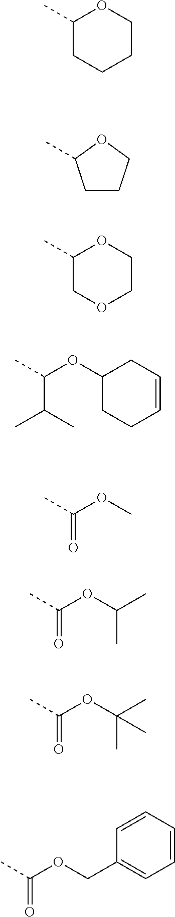

Note that the broken line denotes a valence bond.

Most preferably, the acid labile group R³ in formula (1) is an alkoxymethyl group having the general formula (2).

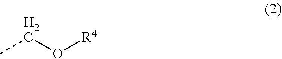

Herein the broken line denotes a valence bond and R⁴ is a monovalent, straight, branched or cyclic C₁-C₁₅ hydrocarbon group.

Illustrative, non-limiting examples of the acid labile group having formula (2) are given below.

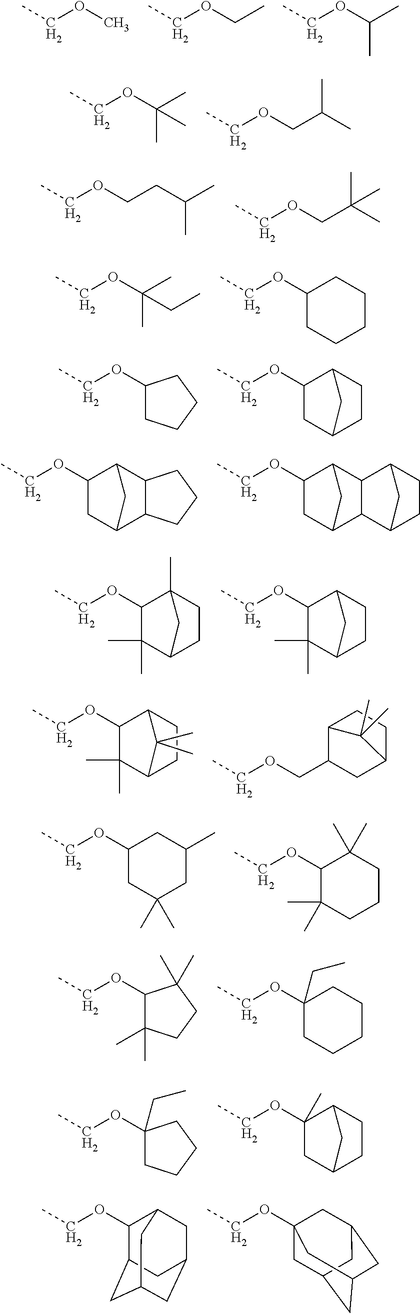

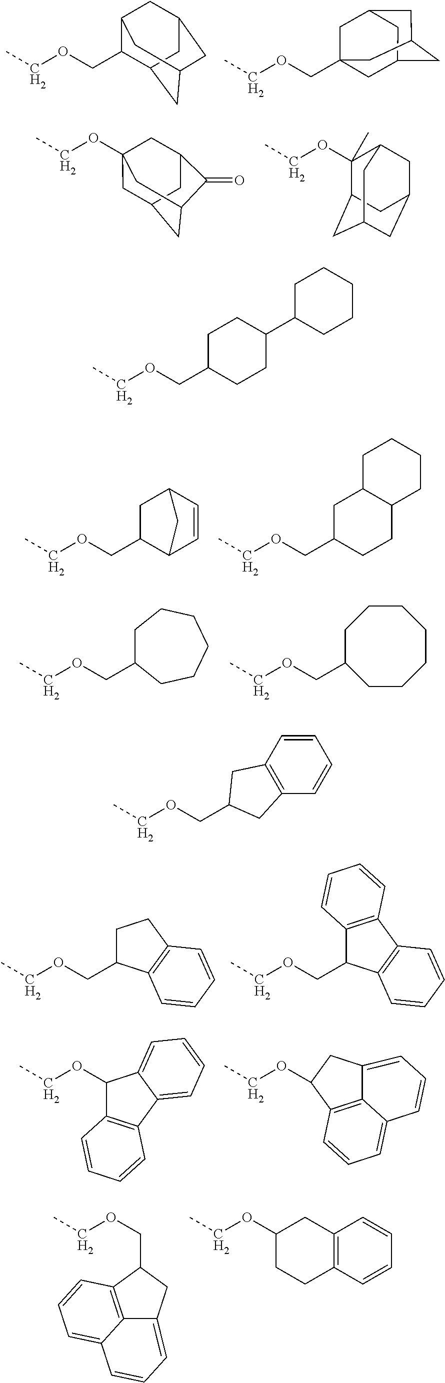

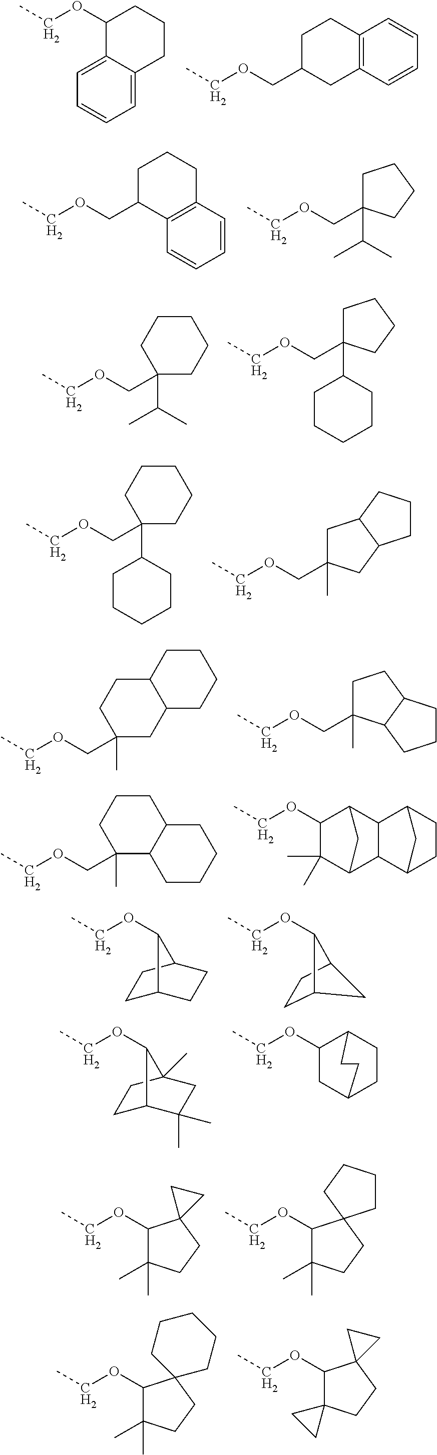

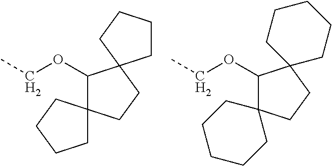

In addition to the recurring units of the structure having a hydroxyl group protected with an acid labile group, the polymer (A) may further comprise recurring units of the structure having a carboxyl group protected with an acid labile group. Such recurring units are exemplified by units of a structure having the general formula (4), but not limited thereto.

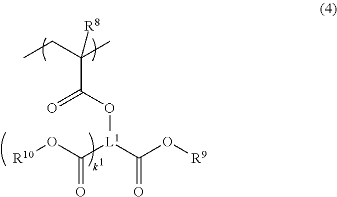

Herein R⁸ is each independently hydrogen or methyl, R⁹ and R¹⁰ each are an acid labile group, and k¹ is 0 or 1. In case k¹=0, L¹ is a single bond, or a divalent, straight, branched or cyclic C₁-C₁₂ hydrocarbon group optionally containing a heteroatom. In case k¹=1, L¹ is a trivalent, straight, branched or cyclic C₁-C₁₂ hydrocarbon group optionally containing a heteroatom.

Illustrative, non-limiting examples of the recurring unit having formula (4) are given below.

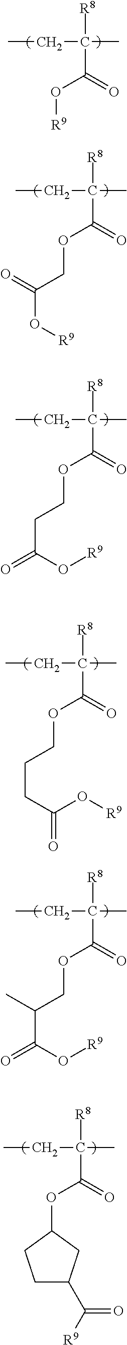

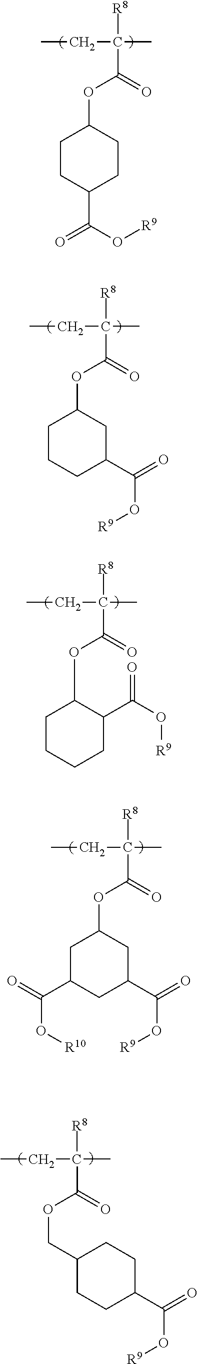

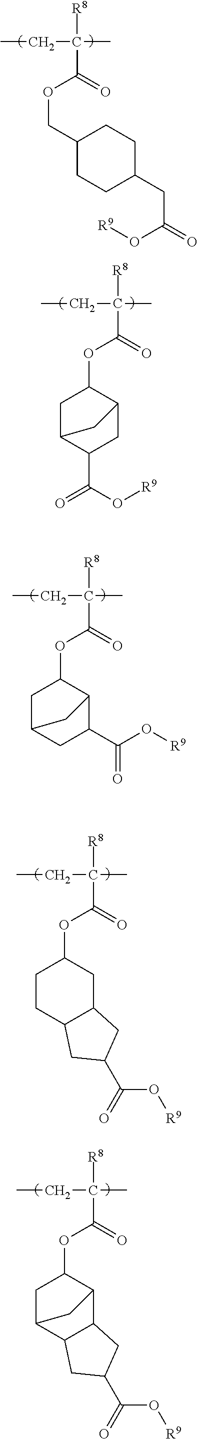

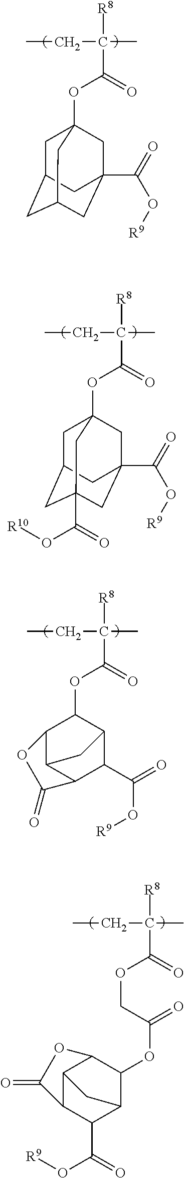

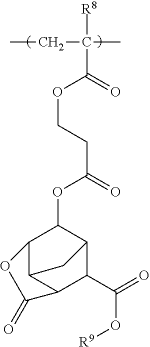

In formula (4), R⁹ and R¹⁰ each are an acid labile group, which is not particularly limited as long as it is deprotected under the action of acid to generate a carboxylic acid. Suitable acid labile groups include those groups of the same structure as the above-illustrated examples of the protective groups R³ and R⁴ on hydroxyl in formula (1) or (2) as well as acid labile groups of the structure having the general formula (5) or (6).

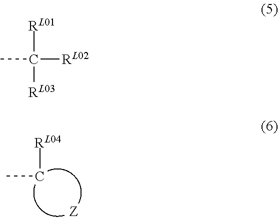

Herein R^{L01} to R^{L03} are each independently C₁-C₁₂ straight, branched or cyclic alkyl, R^{L04} is C₁-C₁₀ straight, branched or cyclic alkyl, Z is a divalent C₂-C₁₅ hydrocarbon group to form a monocyclic or bridged ring with the carbon atom to which it is attached.

Illustrative examples of the acid labile groups having formulae (5) and (6) are given below.

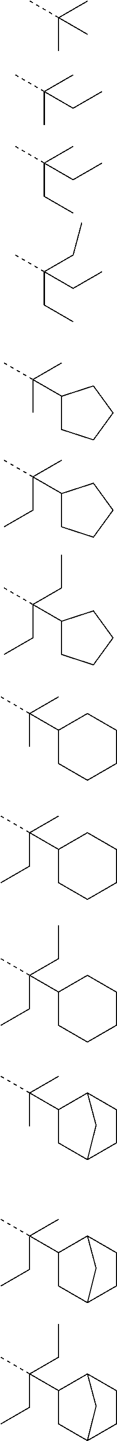

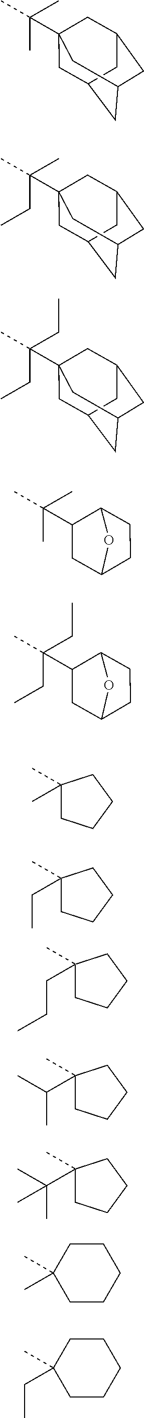

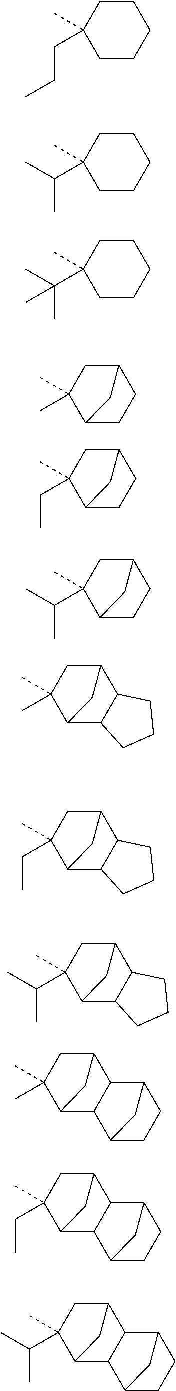

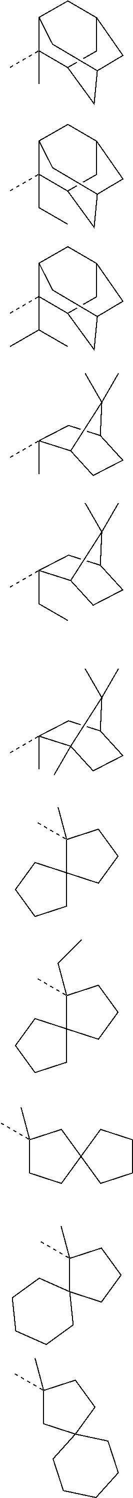

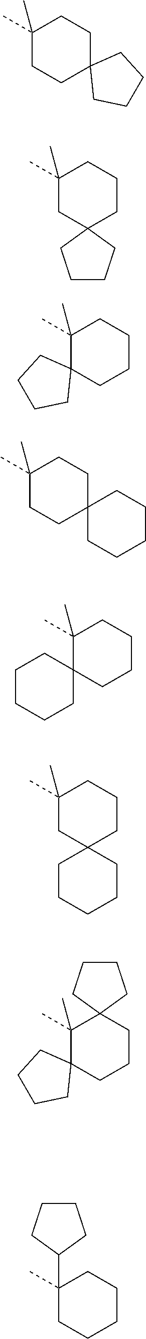

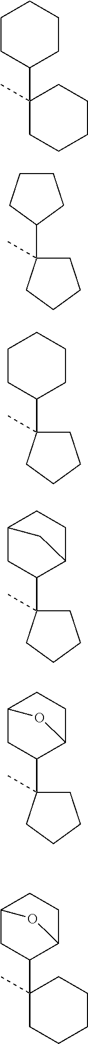

Preferably the polymer (A) may further comprise recurring units having a polar functional group such as hydroxyl, carboxyl, cyano, carbonyl, ether, ester, carbonic acid ester, or sulfonic acid ester as the adhesive group.

The recurring units having a hydroxyl group include those units of the exemplified structure of formula (1) in which the hydroxyl group is not protected with the acid labile group, and units of the following structure, but are not limited thereto.

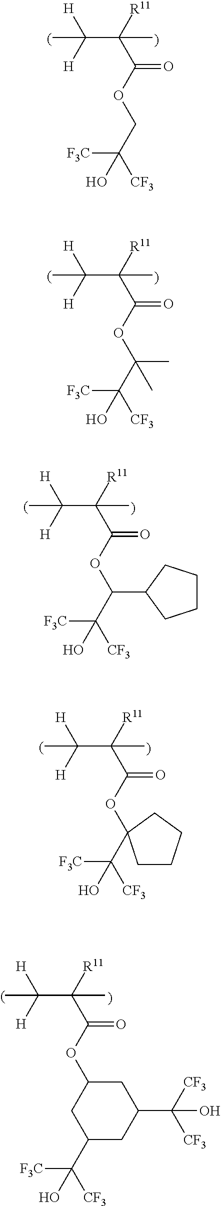

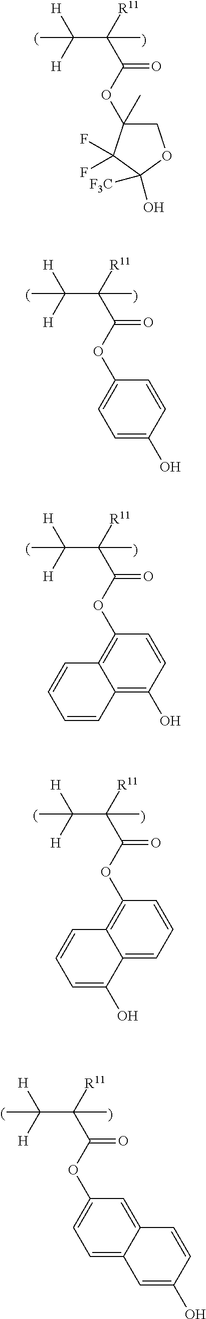

Herein R¹¹ is hydrogen, methyl or trifluoromethyl.

The recurring units having a carboxyl group include those units of the exemplified structure of formula (4) in which the carboxyl group is not protected with the acid labile group, but are not limited thereto.

Examples of the recurring units having a polar functional group such as cyano, carbonyl, ether, ester, carbonic acid ester or sulfonic acid ester are given below, but not limited thereto.

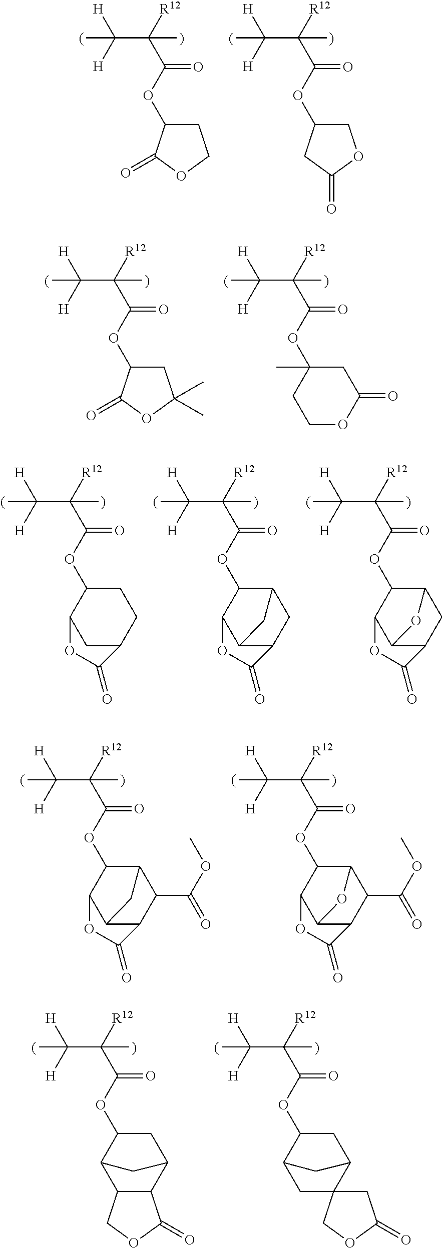

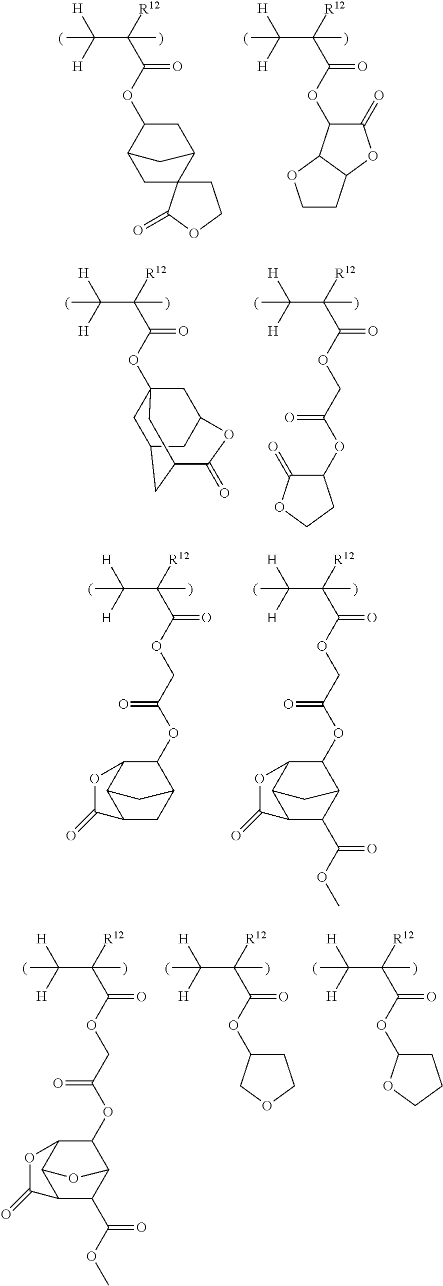

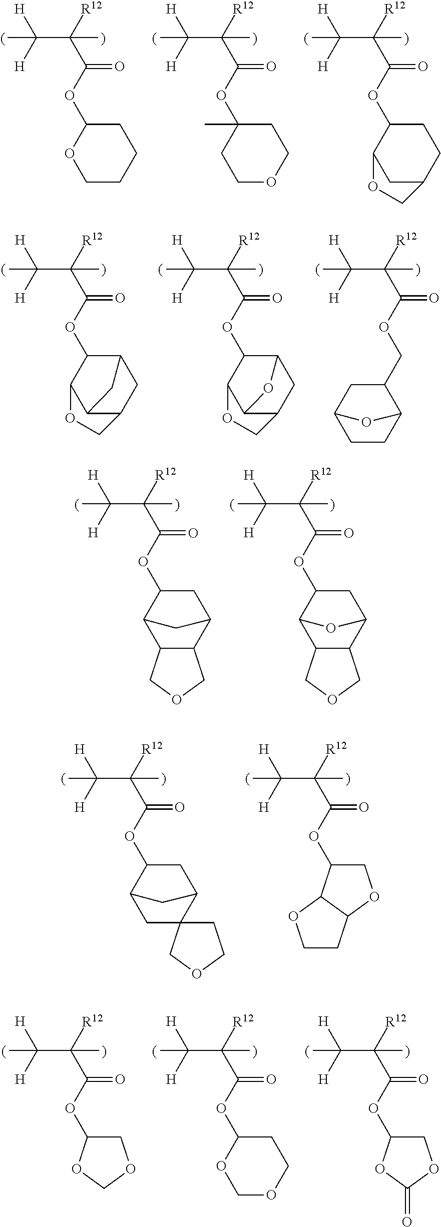

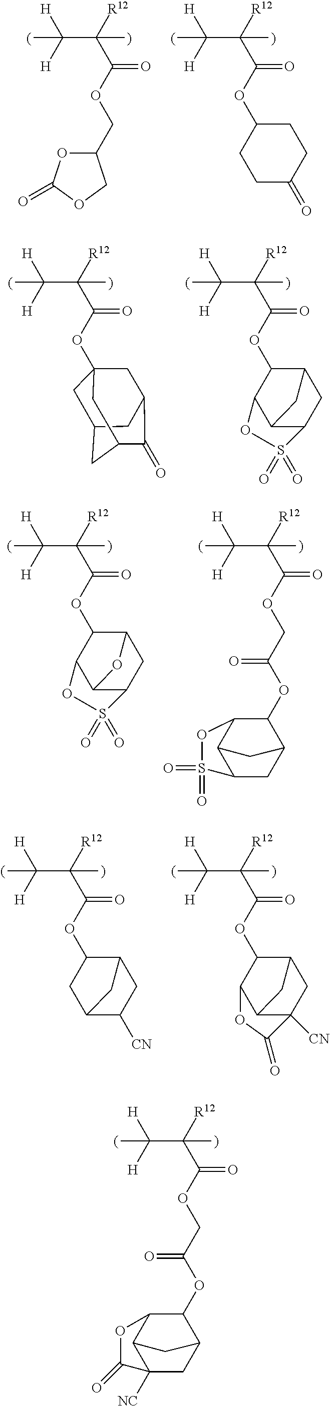

Herein R¹² is hydrogen, methyl or trifluoromethyl.

The polymer (A) may further comprise a sulfonium salt of the structure having the general formula (p1), (p2) or (p3).

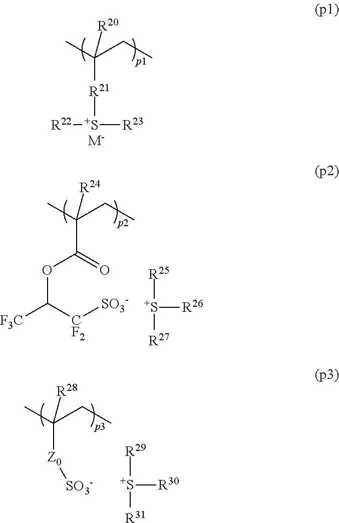

Herein R²⁰, R²⁴ and R²⁸ each are hydrogen or methyl. R²¹ is a single bond, phenylene, —O—R³³—, or —C(═O)—Y—R³³— wherein Y is oxygen or NH, and R³³ is a straight, branched or cyclic C₁-C₆ alkylene group, alkenylene group or phenylene group, which may contain a carbonyl (—CO—), ester (—COO—), ether (—O—) or hydroxyl radical. R²², R²³, R²⁵, R²⁶, R²⁷, R²⁹, R³⁰, and R³¹ are each independently a straight, branched or cyclic C₁-C₁₂ alkyl group which may contain a carbonyl, ester or ether radical, or a C₆-C₁₂ aryl, C₇-C₂₀ aralkyl, or thiophenyl group. Z₀ is a single bond, methylene, ethylene, phenylene, fluorophenylene, —O—R³²—, or —C(═O)—Z₁—R³²— wherein Z₁ is oxygen or NH, and R³² is a straight, branched or cyclic C₁-C₆ alkylene group, alkenylene group or phenylene group, which may contain a carbonyl, ester, ether or hydroxyl radical. M⁻ is a non-nucleophilic counter ion.

Preferably, the polymer (A) is constructed of the above recurring units in a particular molar ratio. Provided that “a1” represents a total content of recurring units of the structure having a hydroxyl group protected with an acid labile group, “a2” represents a total content of recurring units of the structure having a carboxyl group protected with an acid labile group, “a3” represents a total content of recurring units having a polar functional group such as hydroxyl, carboxyl, cyano, carbonyl, ether, ester, carbonic acid ester, or sulfonic acid ester, “p” represents a total content of sulfonium salt units of the structure having formula (p1), (p2) or (p3), and a1+a2+a3+p=1, these molar ratios are preferably in the range: 0.1≦a1≦0.9, 0≦a2≦0.5, 0≦a3≦0.9, and 0≦p≦0.2; more preferably 0.2≦a1≦0.7, 0≦a2≦0.3, 0.3≦a3≦0.8, and 0≦p≦0.1, and 0.3≦a1+a2≦0.7.

The polymer (A) should preferably have a weight average molecular weight (Mw) in the range of 3,000 to 100,000, and more preferably 5,000 to 50,000, as measured by GPC versus polystyrene standards using tetrahydrofuran solvent. Although the dispersity (Mw/Mn) of the polymer is not particularly limited, a dispersity (Mw/Mn) of 1.0 to 3.0 indicating a narrow molecular weight distribution is preferred because acid diffusion is restrained and resolution is improved.

The resist composition further comprises (B) a compound capable of generating an acid in response to high-energy radiation (known as “acid generator”) and (C) an organic solvent.

Typical of the acid generator used herein is a photoacid generator (PAG). The PAG may preferably be compounded in an amount of 0.5 to 30 parts and more preferably 1 to 20 parts by weight per 100 parts by weight of the base resin. The PAG is any compound capable of generating an acid upon exposure to high-energy radiation. Suitable PAGs include sulfonium salts, iodonium salts, sulfonyldiazomethane, N-sulfonyloxyimide, and oxime-O-sulfonate acid generators. The PAGs may be used alone or in admixture of two or more. Examples of the PAG are described in JP-A 2008-111103, paragraphs [0123] to [0138] (U.S. Pat. No. 7,537,880).

Examples of the organic solvent used herein are described in JP-A 2008-111103, paragraph [0144] (U.S. Pat. No. 7,537,880). Specifically, exemplary solvents include ketones such as cyclohexanone and methyl-2-n-amyl ketone; alcohols such as 3-methoxybutanol, 3-methyl-3-methoxybutanol, 1-methoxy-2-propanol, and 1-ethoxy-2-propanol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone, and mixtures thereof. A high-boiling alcohol solvent is also useful, for example, diethylene glycol, propylene glycol, glycerol, 1,4-butane diol or 1,3-butane diol. An appropriate amount of the organic solvent is 100 to 10,000 parts, preferably 300 to 8,000 parts by weight per 100 parts by weight of the base resin.

The resist composition further comprises (D) a polymeric additive which comprises recurring units having at least one fluorine atom and is free of hydroxyl.

It is a common practice to add a fluorinated polymer to a resist solution containing a polymer as base resin so that the fluorinated polymer may render the surface of a resist film as coated more water repellent, thereby enabling the immersion lithography without a need for topcoat. In particular, a polymer having a 1,1,1,3,3,3-hexafluoro-2-propanol residue is regarded appropriate because it readily dissolves in alkaline developer, with exemplary polymers described in JP-A 2007-297590 and JP-A 2008-111103. However, for the purpose of improving the dynamic contact angle (i.e., receding contact angle or sliding angle) which is critical in the water-mediated immersion lithography, it is further preferred that the fluorinated polymeric additive be free of a hydroxyl group as typified by 1,1,1,3,3,3-hexafluoro-2-propanol residue.

The polymeric additive (D) should be fully soluble in a developer, in order to avoid deformation of pattern profile and formation of foreign matter due to under-development. If a polymeric additive is free of a hydroxyl group, especially an acidic hydroxyl group such as 1,1,1,3,3,3-hexafluoro-2-propanol residue, then this polymeric additive is unsuitable for positive development in an aqueous alkaline solution developer because of shortage of solubility. For negative development in an organic solvent developer, however, this polymeric additive exhibits sufficient solubility despite the lack of hydroxyl group.

On negative development in an organic solvent developer, the fluorinated polymeric additive free of hydroxyl is improved in collapse resistance of line pattern over the hydroxyl-containing fluorinated polymeric additive so that a finer line pattern may be resolved. The hydroxyl-free fluorinated polymeric additive has a greater tendency to segregate at the resist film surface and be substantially absent in the depth of resist film or near the substrate, than the hydroxyl-containing fluorinated polymeric additive. Presumably, this tendency avoids a phenomenon that a developer penetrates into the pattern to cause it to collapse while the fluorinated polymeric additive having a high developer dissolution rate serves as a path therefor.

The polymeric additive (D) is added in an amount of 1 to 30% by weight based on the total weight of all polymers including polymer (A) and additive (D). Less than 1 wt % of the polymeric additive may be too short to render the resist film surface water repellent whereas more than 30 wt % may detract from dissolution contrast and resolution.

The polymeric additive (D) is not particularly limited as long as it comprises a recurring unit having at least one fluorine atom and is free of hydroxyl. The structure of the polymeric additive is not particularly limited. Examples of the recurring unit having at least one fluorine atom are given below, but not limited thereto.

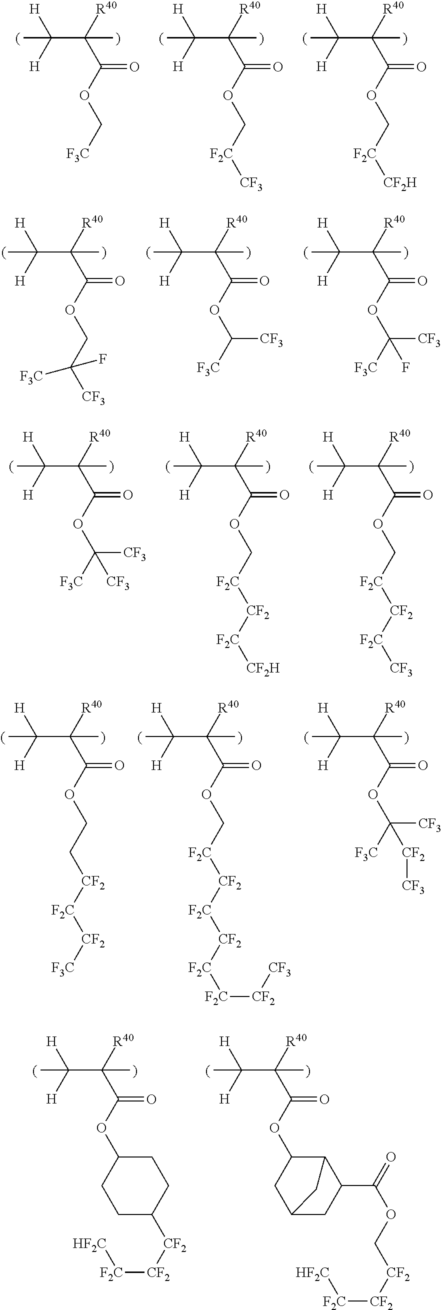

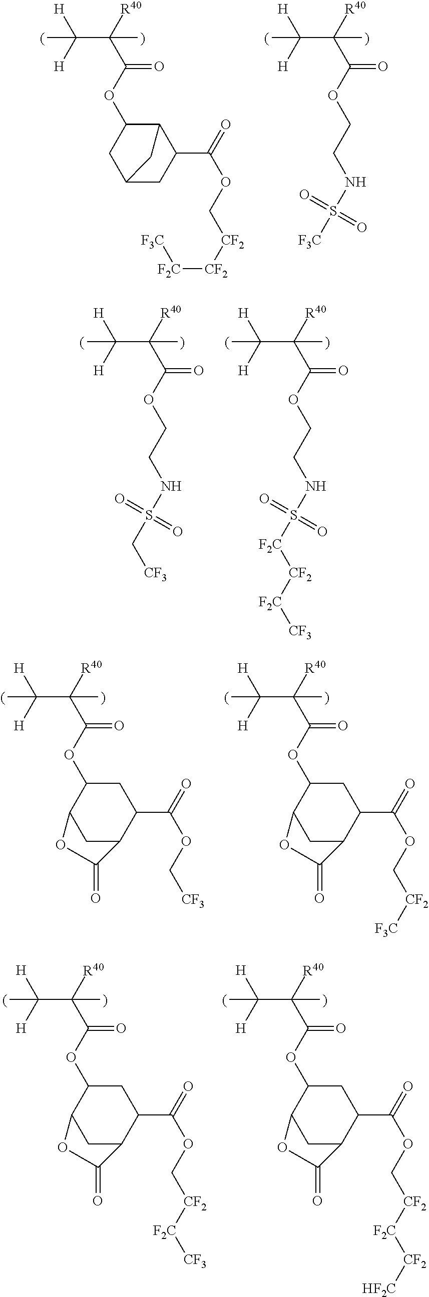

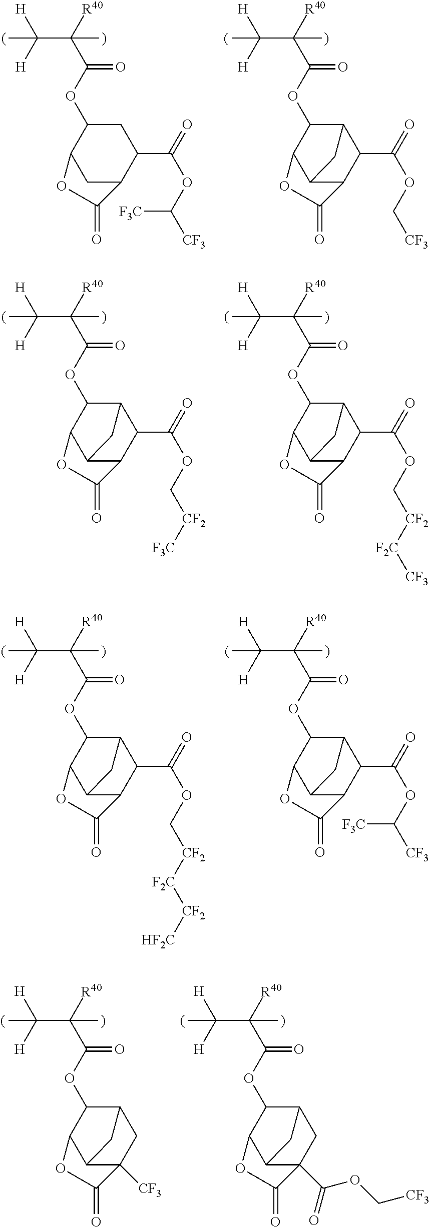

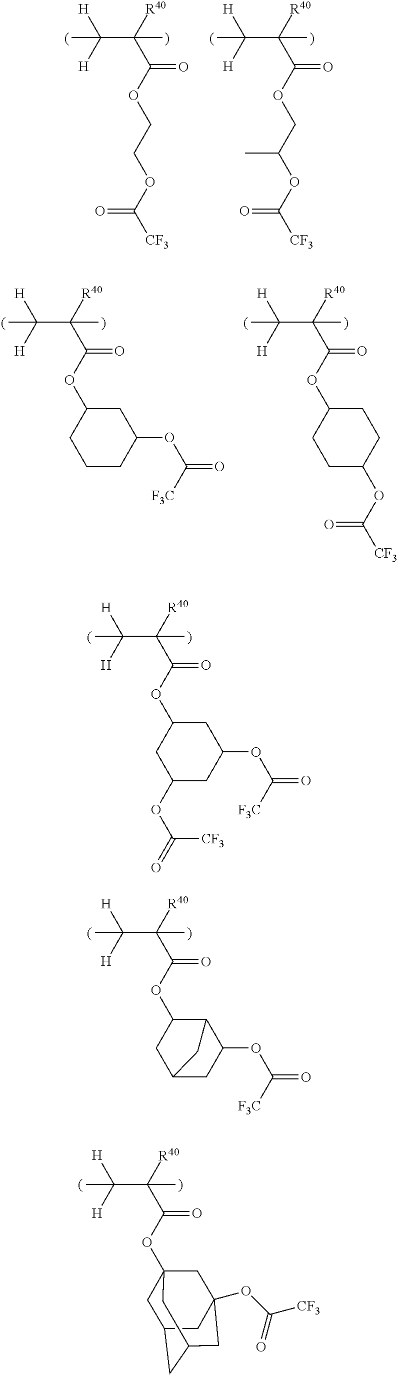

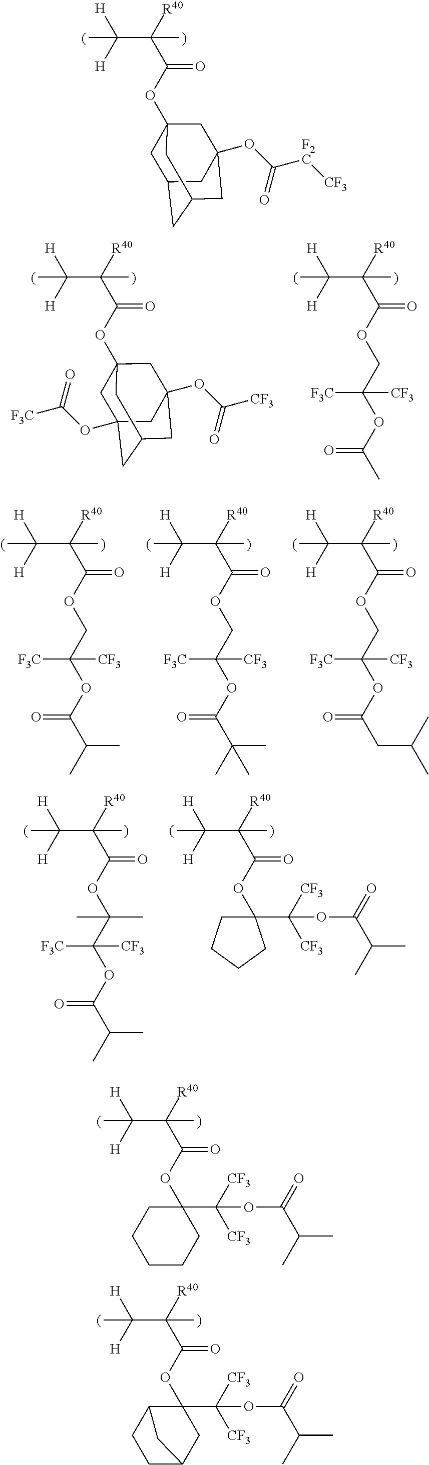

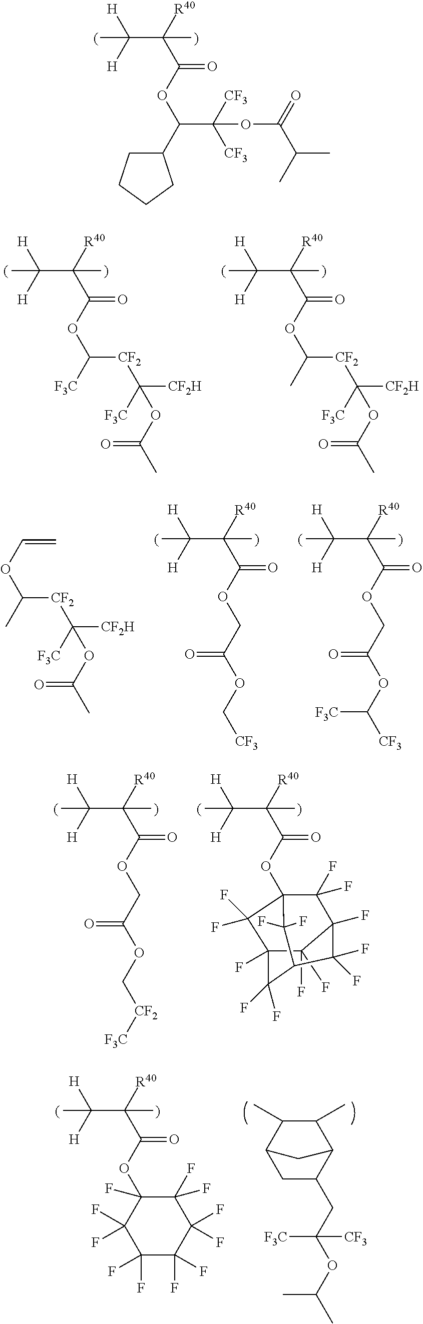

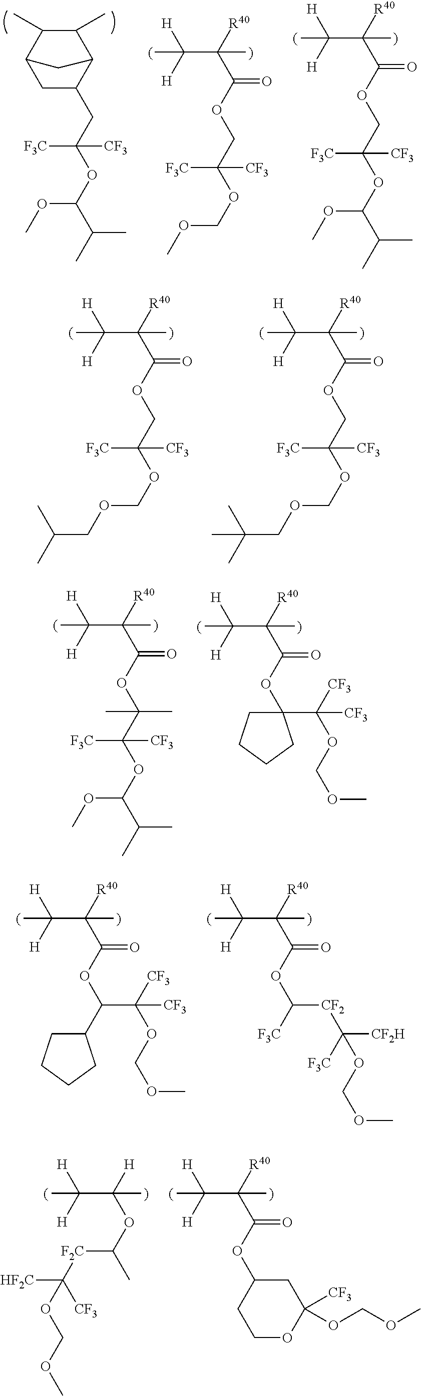

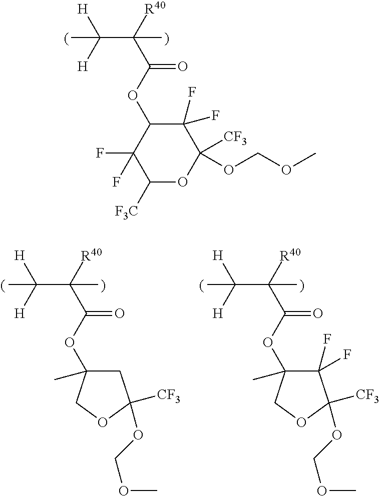

Herein R⁴⁰ is hydrogen, methyl or trifluoromethyl.

Most preferred among the recurring units having at least one fluorine atom in the polymeric additive (D) are units having the general formula (3).

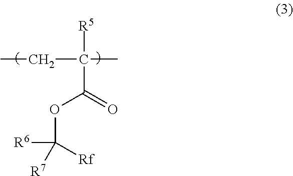

Herein R⁵ is hydrogen, methyl or trifluoromethyl. R⁶ and R⁷ are each independently hydrogen or a straight, branched or cyclic C₁-C₁₅ alkyl group, or R⁶ and R⁷ may bond together to form a ring with the carbon atom to which they are attached, specifically C₅-C₁₂ non-aromatic ring. Rf is a straight or branched C₁-C₁₅ alkyl group in which at least one hydrogen atom is substituted by a fluorine atom.

Examples of the recurring units of the structure having formula (3) are given below, but not limited thereto.

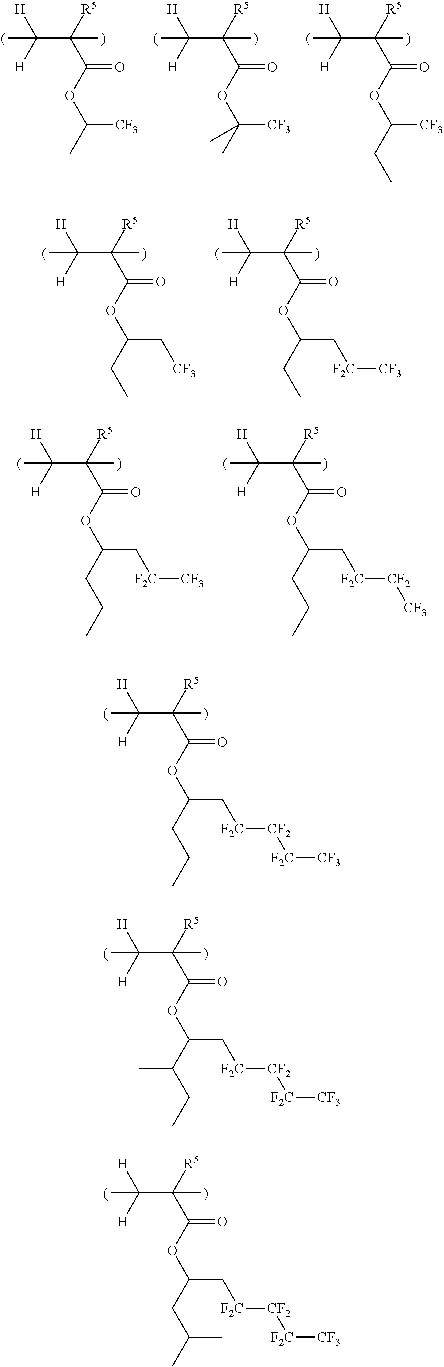

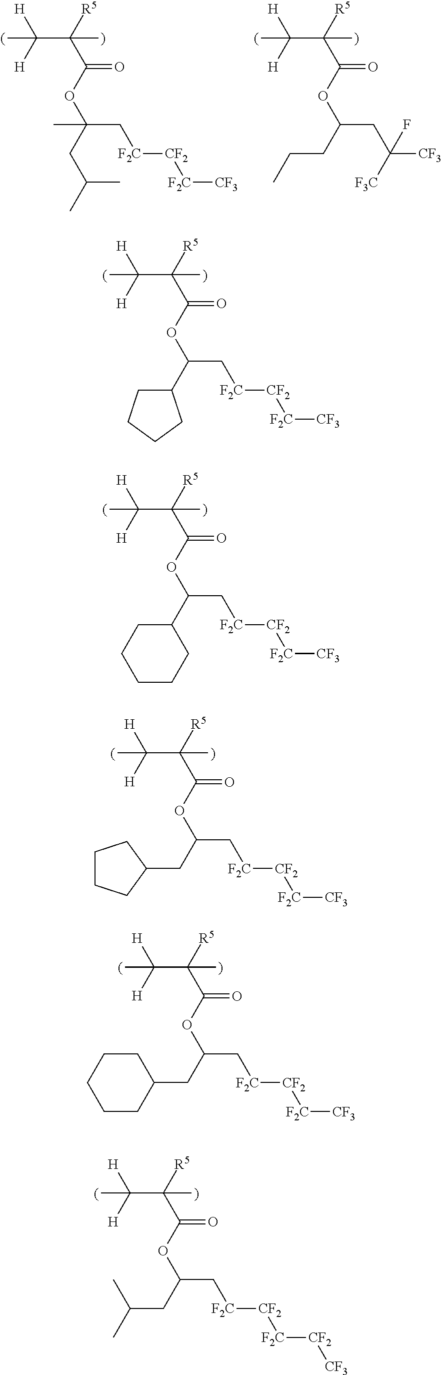

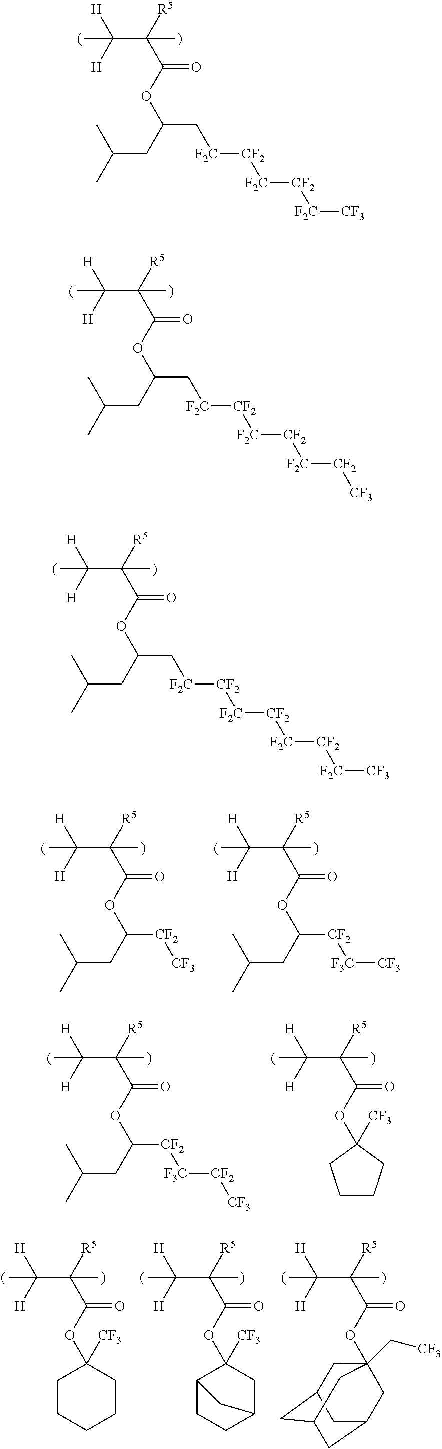

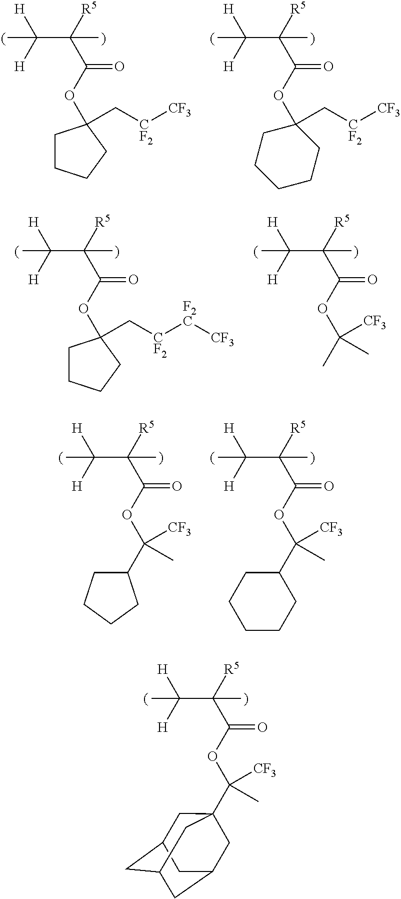

Herein R⁵ is as defined above.

In addition to the fluorinated recurring units, the polymeric additive (D) may further comprise recurring units having a straight, branched or cyclic alkyl group. The additional recurring units may contain an ether bond, ester bond or carbonyl group while they should not contain hydroxyl. Examples of the additional recurring units are given below, but not limited thereto.

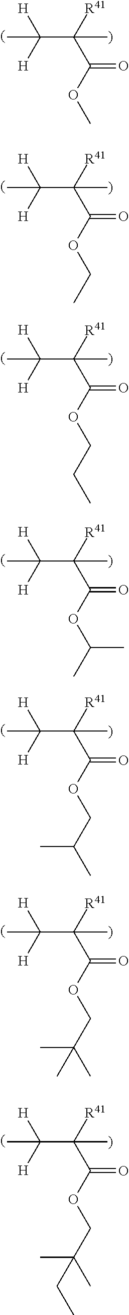

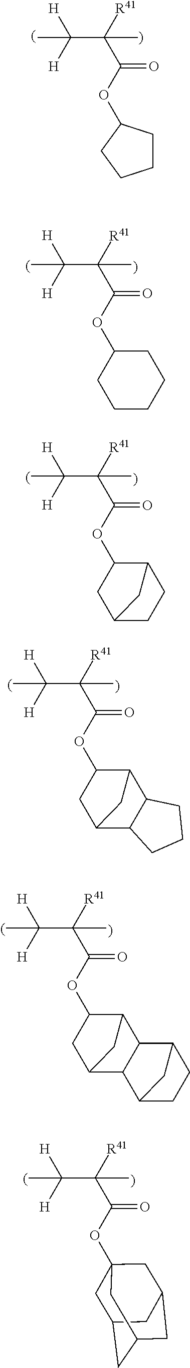

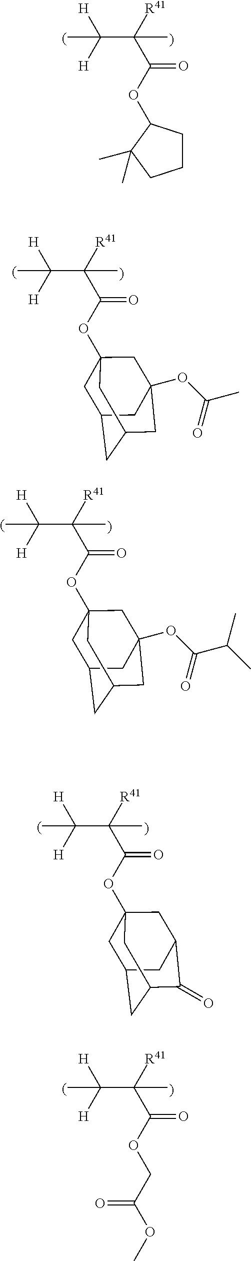

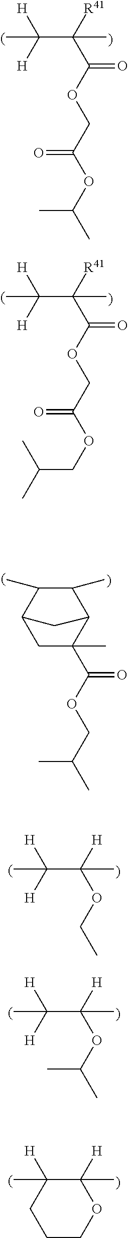

Herein R⁴¹ is hydrogen, methyl or trifluoromethyl.

The polymeric additive (D) may further comprise recurring units of the structure having a carboxyl group protected with an acid labile group. Examples of such recurring units are the same as enumerated in conjunction with formula (4).

If desired, the polymeric additive (D) may further comprise recurring units having an amino group or amine salt. The amino group or amine salt is fully effective for controlling diffusion of acid generated in the exposed region of photoresist to the unexposed region, and thus preventing any trench or hole opening failure. Examples of the recurring units having an amino group or amine salt are given below, but not limited thereto.

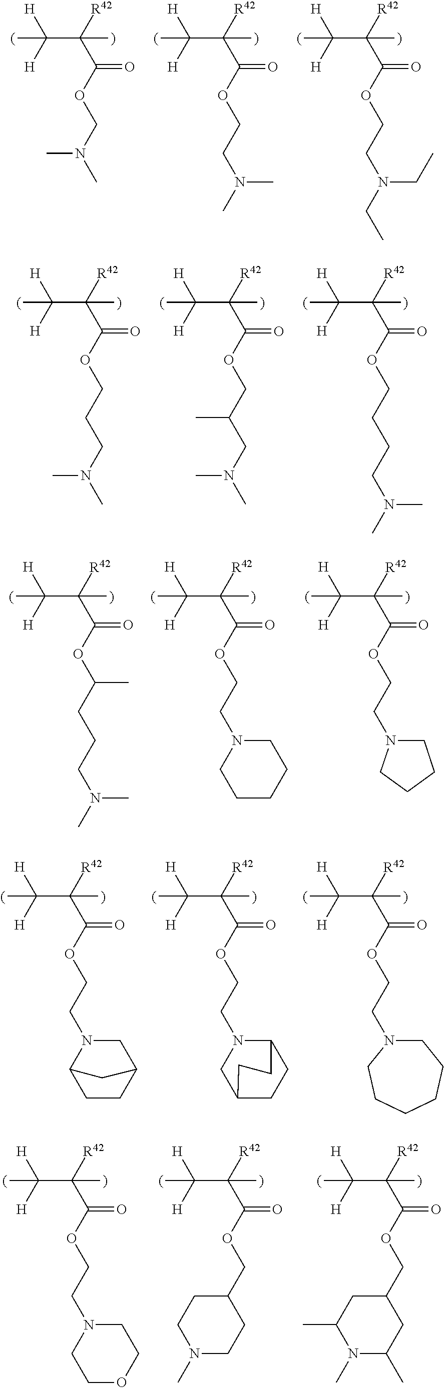

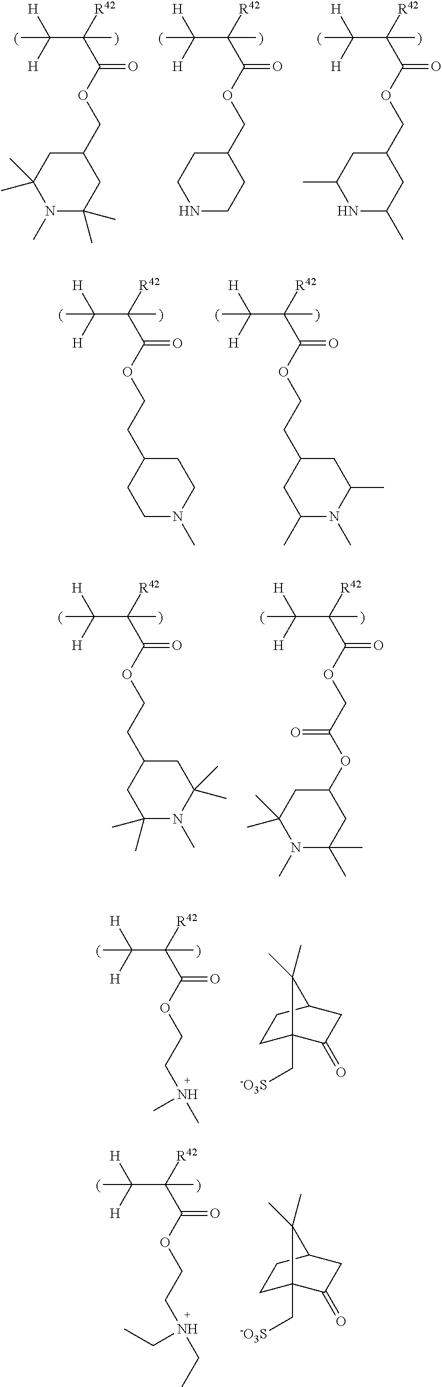

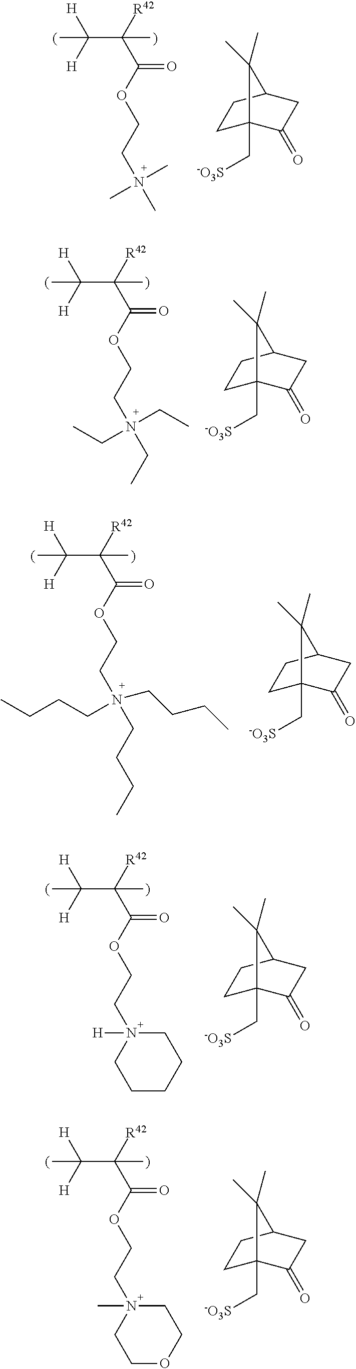

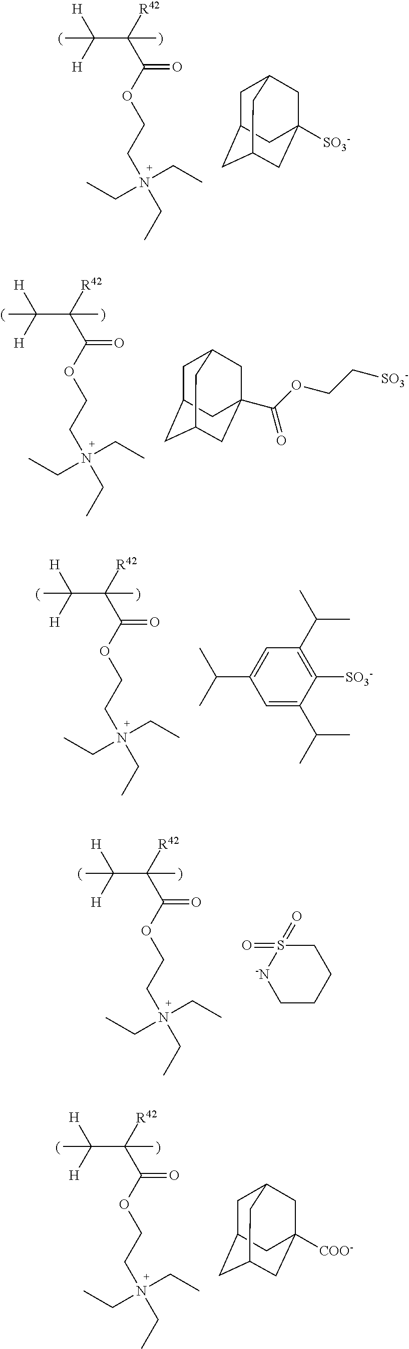

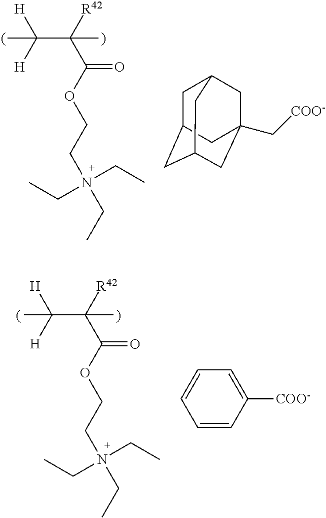

Herein R⁴² is hydrogen, methyl or trifluoromethyl.

Preferably, the polymeric additive (D) is constructed of the above recurring units in a particular molar ratio. Provided that “d1” represents a total content of recurring units having at least one fluorine atom, “d2” represents a total content of recurring units having straight, branched or cyclic alkyl, “d3” represents a total content of recurring units having a carboxyl group protected with an acid labile group, “d4” represents a total content of recurring units having an amino group or amine salt, and d1+d2+d3+d4=1, these molar ratios are preferably in the range: 0.3≦d1≦1, 0≦d2≦0.7, 0≦d3≦0.7, and 0≦d4≦0.5; more preferably 0.5≦d1≦1, 0≦d2≦0.5, 0≦d3≦0.5, and 0≦d4≦0.2.

The polymeric additive (D) should preferably have a weight average molecular weight (Mw) in the range of 3,000 to 100,000, and more preferably 5,000 to 50,000, as measured by GPC versus polystyrene standards using tetrahydrofuran solvent. Although the dispersity (Mw/Mn) of the polymeric additive is not particularly limited, a dispersity (Mw/Mn) of 1.0 to 3.0 indicating a narrow molecular weight distribution is preferred because acid diffusion is restrained and resolution is improved.

While the resist composition comprises the polymer (A), PAG (B), organic solvent (C), and polymeric additive (D) as essential components, the composition may comprise one or more optional components selected from quencher, surfactant, dissolution regulator, and acetylene alcohol.

The quencher is a component having a function of trapping and deactivating the acid generated by the acid generator. As is known in the art, the quencher is effective, when added in an appropriate amount, for adjusting sensitivity, improving dissolution contrast, and improving resolution by restraining acid diffusion into the unexposed region.

Typical quenchers are basic compounds. Exemplary basic compounds include primary, secondary and tertiary amine compounds, specifically amine compounds having a hydroxyl, ether, ester, lactone, cyano or sulfonic ester group, as described in JP-A 2008-111103, paragraphs [0148] to [0163], and nitrogen-containing organic compounds having a carbamate group, as described in JP 3790649. When added, an amount of the basic compound used is preferably 0.01 to 10 parts, more preferably 0.1 to 5 parts by weight per 100 parts by weight of the base resin.

An onium salt compound having an anion combined with weak acid as conjugate acid may be used as the quencher. The quenching mechanism is based on the phenomenon that a strong acid generated by the acid generator is converted into an onium salt through salt exchange reaction. With an weak acid resulting from salt exchange, deprotection reaction of the acid labile group in the base resin does not take place, and so the weak acid onium salt compound in this system functions as a quencher. Onium salt quenchers include onium salts such as sulfonium salts, iodonium salts and ammonium salts of sulfonic acids which are not fluorinated at α-position as described in US 2008153030 (JP-A 2008-158339), and similar onium salts of carboxylic acid. These onium salts can function as the quencher when they are combined with acid generators capable of generating an α-position fluorinated sulfonic acid, imide acid or methide acid. When onium salt quenchers are photo-decomposable like sulfonium salts and iodonium salts, their quench capability is reduced in a high light intensity portion, whereby dissolution contrast is improved. When a negative pattern is formed by organic solvent development, the pattern is thus improved in rectangularity. When added, an amount of the onium salt compound used is preferably 0.05 to 20 parts, more preferably 0.2 to 10 parts by weight per 100 parts by weight of the base resin.

The quenchers including the nitrogen-containing organic compounds and onium salt compounds mentioned above may be used alone or in admixture of two or more.

Suitable surfactants are described in JP-A 2008-111103, paragraph [0166]. Suitable dissolution regulators are described in JP-A 2008-122932, paragraphs [0155] to [0178]. Suitable acetylene alcohols are described in JP-A 2008-122932, paragraphs [0179] to [0182]. When added, the surfactant may be used in any desired amount as long as the objects of the invention are not impaired.

Also another polymeric additive may be added for improving the water repellency on surface of a resist film as spin coated. This additive may be used in the topcoatless immersion lithography. These additives have a specific structure with a 1,1,1,3,3,3-hexafluoro-2-propanol residue and are described in JP-A 2007-297590 and JP-A 2008-111103. The water repellency improver to be added to the resist composition should be soluble in the organic solvent as developer. The water repellency improver of specific structure with a 1,1,1,3,3,3-hexafluoro-2-propanol residue is well soluble in the developer. A polymer having an amino group or amine salt copolymerized as recurring units may serve as the water repellency improver and is effective for preventing evaporation of acid during PEB and avoiding any hole pattern opening failure after development. When added, an appropriate amount of the water repellency improver is 0.1 to 20 parts, preferably 0.5 to 10 parts by weight per 100 parts by weight of the base resin.

### Process

Another embodiment of the invention is a pattern forming process comprising the steps of applying a resist composition as defined above onto a substrate, prebaking to form a resist film, exposing, baking, and developing the exposed film in an organic solvent-based developer to selectively dissolve the unexposed region of resist film, thereby forming a negative pattern.

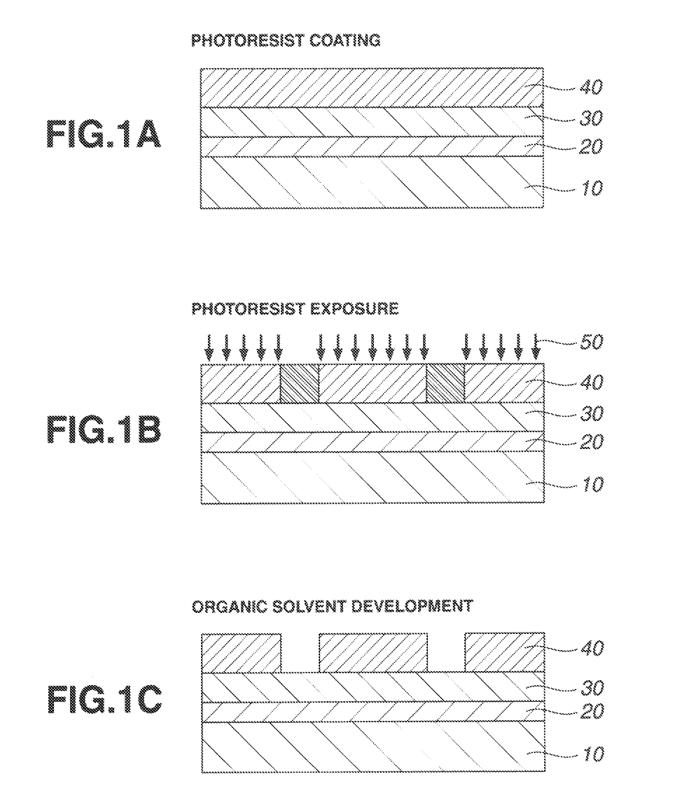

Now referring to the drawings, the pattern forming process of the invention is illustrated in FIG. 1. First, the resist composition is coated on a substrate to form a resist film thereon. Specifically, a resist film 40 of the resist composition is formed on a processable layer 20 disposed on a substrate 10 directly or via an intermediate intervening layer 30 as shown in FIG. 1A. The resist film preferably has a thickness of 10 to 1,000 nm and more preferably 20 to 500 nm. After coating and prior to exposure, the resist coating is heated (or post-applied bake, PAB). The preferred PAB conditions include a temperature of 60 to 180° C., especially 70 to 150° C. and a time of 10 to 300 seconds, especially 15 to 200 seconds.

The substrate 10 used herein is generally a silicon substrate. The processable layer (or target film) 20 used herein includes SiO₂, SiN, SiON, SiOC, p-Si, α-Si, TiN, WSi, BPSG, SOG, Cr, CrO, CrON, MoSi, low dielectric film, and etch stopper film. The intermediate intervening layer 30 includes hard masks of SiO₂, SiN, SiON or p-Si, an undercoat in the form of carbon film, a silicon-containing intermediate film, and an organic antireflective coating.

Next comes exposure depicted at 50 in FIG. 1B. For the exposure, preference is given to high-energy radiation having a wavelength of 140 to 250 nm and EUV having a wavelength of 13.5 nm, and especially ArF excimer laser radiation of 193 nm. The exposure may be done either in a dry atmosphere such as air or nitrogen stream or by immersion lithography in water. The ArF immersion lithography uses deionized water or liquids having a refractive index of at least 1 and highly transparent to the exposure wavelength such as alkanes as the immersion solvent. The immersion lithography involves exposing the baked (PAB) resist film to light through a projection lens, with water or liquid introduced between the resist film and the projection lens. Since this allows lenses to be designed to a NA of 1.0 or higher, formation of finer feature size patterns is possible. The immersion lithography is important for the ArF lithography to survive to the 45-nm node. In the case of immersion lithography, deionized water rinsing (or post-soaking) may be carried out after exposure for removing water droplets left on the resist film, or a protective film may be applied onto the resist film after PAB for preventing any leach-out from the resist film and improving water slip on the film surface.

The resist protective film used in the immersion lithography is preferably formed from a solution of a polymer having 1,1,1,3,3,3-hexafluoro-2-propanol residues which is insoluble in water, but soluble in an alkaline developer, in a solvent selected from alcohols of at least 4 carbon atoms, ethers of 8 to 12 carbon atoms, and mixtures thereof. One typical protective film-forming composition may comprise a polymer derived from a monomer having a 1,1,1,3,3,3-hexafluoro-2-propanol residue. While the protective film must dissolve in an organic solvent-based developer, the polymer comprising recurring units having a 1,1,1,3,3,3-hexafluoro-2-propanol residue dissolves in the organic solvent-based developer. In particular, protective films formed from the compositions based on a polymer having 1,1,1,3,3,3-hexafluoro-2-propanol residues as described in JP-A 2007-025634 and JP-A 2008-003569 readily dissolve in the organic solvent-based developer.

In the protective film-forming composition, an amine compound or amine salt may be added, or a polymer having copolymerized therein recurring units containing an amino group or amine salt may be used as the base resin. This component is effective for controlling diffusion of the acid generated in the exposed region of the resist film to the unexposed region for thereby preventing any hole opening failure. A useful protective film-forming composition having an amine compound added thereto is described in JP-A 2008-003569. A useful protective film-forming composition containing a polymer having an amino group or amine salt copolymerized therein is described in JP-A 2007-316448. The amine compound or amine salt may be selected from the compounds enumerated as the basic compound to be added to the resist composition. An appropriate amount of the amine compound or amine salt added is 0.01 to 10 parts, preferably 0.02 to 8 parts by weight per 100 parts by weight of the base resin.

After formation of the resist film, deionized water rinsing (or post-soaking) may be carried out for extracting the acid generator and other components from the film surface or washing away particles, or after exposure, rinsing (or post-soaking) may be carried out for removing water droplets left on the resist film. If the acid evaporating from the exposed region during PEB deposits on the unexposed region to deprotect the protective group on the surface of the unexposed region, there is a possibility that the surface edges of holes after development are bridged to close the holes. Particularly in the case of negative development, regions surrounding the holes receive light so that acid is generated therein. There is a possibility that the holes are not opened if the acid outside the holes evaporates and deposits inside the holes during PEB. Provision of a protective film is effective for preventing evaporation of acid and for avoiding any hole opening failure. A protective film having an amine compound or amine salt added thereto is more effective for preventing acid evaporation.

The protective film is preferably formed from a composition comprising a polymer bearing a 1,1,1,3,3,3-hexafluoro-2-propanol residue and an amino group or amine salt-containing compound, or a composition comprising a polymer comprising recurring units having a 1,1,1,3,3,3-hexafluoro-2-propanol residue and recurring units having an amino group or amine salt copolymerized, the composition further comprising an alcohol solvent of at least 4 carbon atoms, an ether solvent of 8 to 12 carbon atoms, or a mixture thereof.

Suitable alcohols of 4 or more carbon atoms include 1-butyl alcohol, 2-butyl alcohol, isobutyl alcohol, tert-butyl alcohol, 1-pentanol, 2-pentanol, 3-pentanol, tert-amyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol. Suitable ether solvents of 8 to 12 carbon atoms include di-n-butyl ether, diisobutyl ether, di-sec-butyl ether, di-n-pentyl ether, diisopentyl ether, di-sec-pentyl ether, di-t-amyl ether, and di-n-hexyl ether.

Exposure is preferably performed in an exposure dose of about 1 to 200 mJ/cm², more preferably about 10 to 100 mJ/cm². This is followed by baking (PEB) on a hot plate at 60 to 150° C. for 1 to 5 minutes, preferably at 80 to 120° C. for 1 to 3 minutes.

Thereafter the exposed resist film is developed in an organic solvent-based developer for 0.1 to 3 minutes, preferably 0.5 to 2 minutes by any conventional techniques such as dip, puddle and spray techniques. In this way, the unexposed region of resist film is dissolved away, leaving a negative resist pattern 40 on the substrate 10 as shown in FIG. 1C.

The organic solvent used as the developer is preferably selected from among ketones such as 2-octanone, 2-nonanone, 2-heptanone, 3-heptanone, 4-heptanone, 2-hexanone, 3-hexanone, diisobutyl ketone, 2-methylcyclohexanone, 3-methylcyclohexanone, 4-methylcyclohexanone, acetophenone, 2′-methylacetophenone, and 4′-methylacetophenone; and esters such as propyl acetate, butyl acetate, isobutyl acetate, amyl acetate, butenyl acetate, isoamyl acetate, phenyl acetate, propyl formate, butyl formate, isobutyl formate, amyl formate, isoamyl formate, methyl valerate, methyl pentenoate, methyl crotonate, ethyl crotonate, methyl lactate, ethyl lactate, propyl lactate, butyl lactate, isobutyl lactate, amyl lactate, isoamyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate.

These organic solvents may be used alone or in admixture of two or more. The total amount of organic solvents is preferably at least 60%, more preferably 80 to 100% by weight based on the total weight of the developer. When the total amount of organic solvents is less than 100 wt % of the developer, the remainder may be another organic solvent, which may be selected from alkanes such as octane, decane and dodecane, and alcohols such as isopropyl alcohol, 1-butyl alcohol, 1-pentanol, 1-hexanol, and 4-methyl-2-pentanol. The developer may also contain a surfactant, examples of which are the same as the surfactant which is optionally added to the resist composition.

At the end of development, the resist film is rinsed. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents. Specifically, suitable alkanes of 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Suitable alkenes of 6 to 12 carbon atoms include hexene, heptene, octene, cyclohexene, methylcyclohexene, dimethylcyclohexene, cycloheptene, and cyclooctene. Suitable alkynes of 6 to 12 carbon atoms include hexyne, heptyne, and octyne. Suitable alcohols of 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-amyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol. Suitable ether compounds of 8 to 12 carbon atoms include di-n-butyl ether, diisobutyl ether, di-sec-butyl ether, di-n-pentyl ether, diisopentyl ether, di-sec-pentyl ether, di-tert-amyl ether, and di-n-hexyl ether. The solvents may be used alone or in admixture. Besides the foregoing solvents, aromatic solvents may be used, for example, toluene, xylene, ethylbenzene, isopropylbenzene, tert-butylbenzene and mesitylene.

In forming a trench pattern, negative tone development is often successful in forming an optical image with a higher contrast than positive tone development. As used herein, the term “trench pattern” refers to a line-and-space pattern in which the spaces are narrower than the lines, that is, the space size is smaller than the line width. The pattern in which spaces are separated infinitely apart, that is, the line width is infinitely extended is referred to as “isolated trench pattern.” As the trench (or space) width becomes finer, the negative tone development adapted to form trenches by reversal of a line pattern image on a mask becomes more advantageous to insure a resolution.

The method of forming a hole pattern by negative tone development is typically classified in terms of mask design into the following three methods:

(i) performing exposure through a mask having a dotted light-shielding pattern so that a pattern of holes may be formed at the dots after negative tone development,
(ii) performing exposure through a mask having a lattice-like light-shielding pattern so that a pattern of holes may be formed at the intersections of gratings after negative tone development, and
(iii) performing two exposures using a mask having a lined light-shielding pattern, changing the direction of lines during second exposure from the direction of lines during first exposure so that the lines of the second exposure may intersect with the lines of the first exposure, whereby a pattern of holes is formed at the intersections of lines after negative tone development.

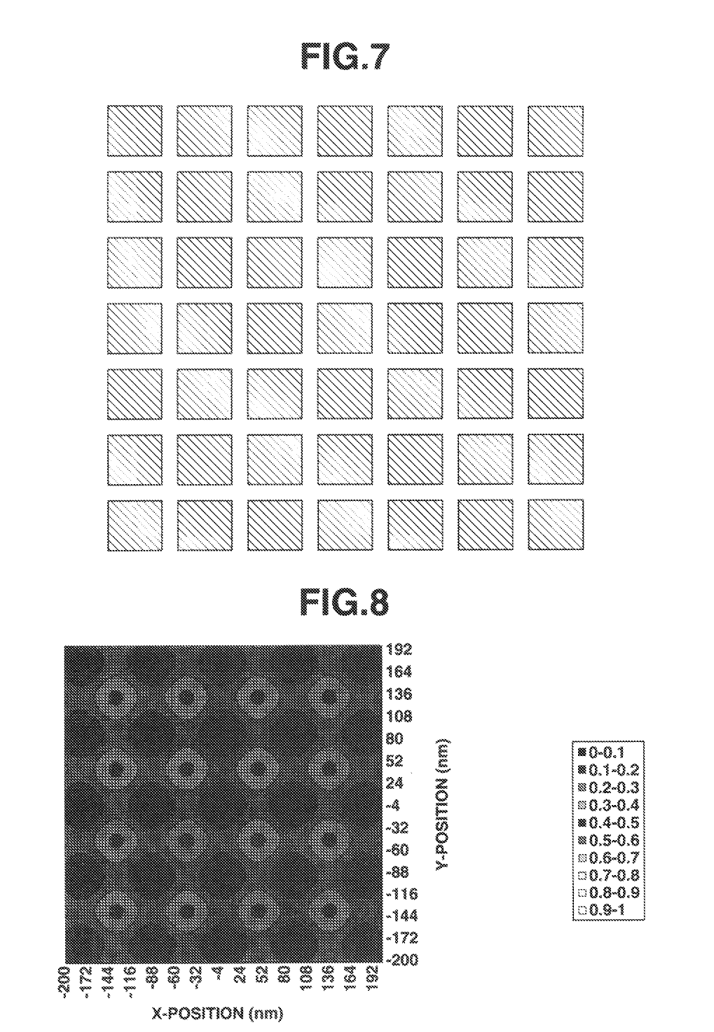

Method (i) uses a mask having a dotted light-shielding pattern as shown in FIG. 7. Although the illumination for exposure used in this method is not particularly limited, a cross-pole illumination or quadra-pole illumination with the aperture configuration shown in FIG. 17 is preferred for the purpose of reducing the pitch. The contrast may be improved by combining the cross-pole illumination with X-Y polarized illumination or azimuthally polarized illumination of circular polarization.

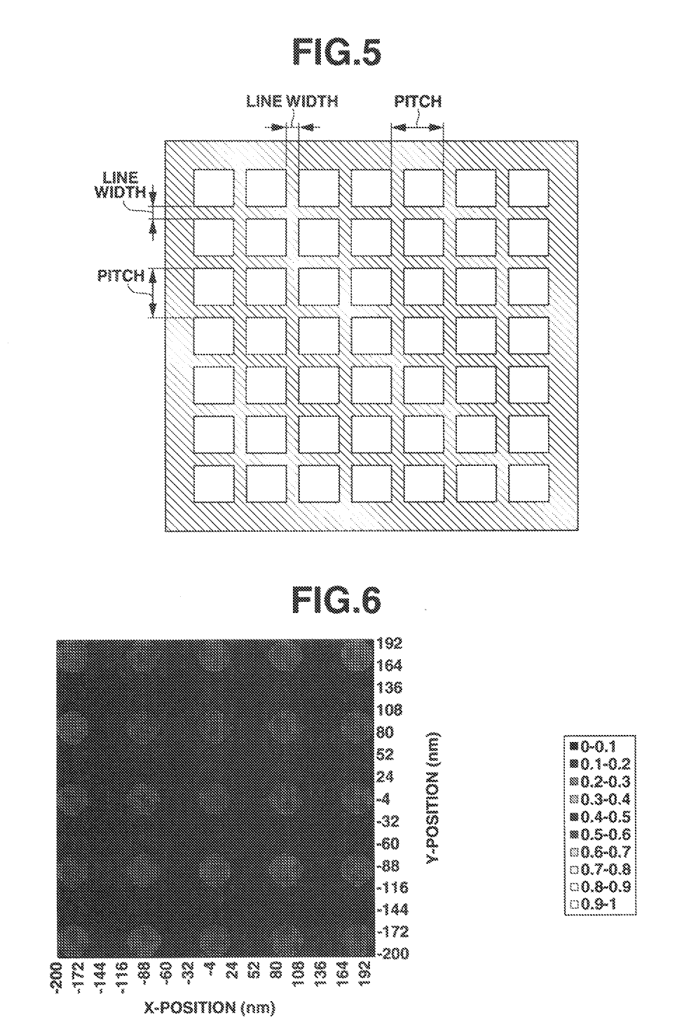

Method (ii) uses a mask having a lattice-like light-shielding pattern as shown in FIG. 5. Like Method (i), a combination of cross-pole illumination with polarized illumination is preferred for the purpose of improving resolution even at a narrow pitch.

On use of a mask bearing a dot pattern of square dots having a pitch of 90 nm and a side width of 60 nm as shown in FIG. 7, under conditions: NA 1.3 lens, cross-pole illumination, 6% halftone phase shift mask, and azimuthally polarized illumination, an optical image is obtained as shown in FIG. 8 that depicts the contrast thereof. On use of a mask bearing a lattice-like line pattern having a pitch of 90 nm and a line width of 30 nm as shown in FIG. 5, under conditions: NA 1.3 lens, cross-pole illumination, 6% halftone phase shift mask, and azimuthally polarized illumination, an optical image is obtained as shown in FIG. 6. As compared with the use of the dot pattern, the use of the lattice-like pattern has the advantage of enhanced optical contrast despite the drawback of reduced resist sensitivity due to reduced light intensity.

In Method (ii), the procedure of using a half-tone phase shift mask having a transmittance of 3 to 15% and converting the intersections of lattice-like shifter gratings into a pattern of holes after development is preferred because the optical contrast is improved.

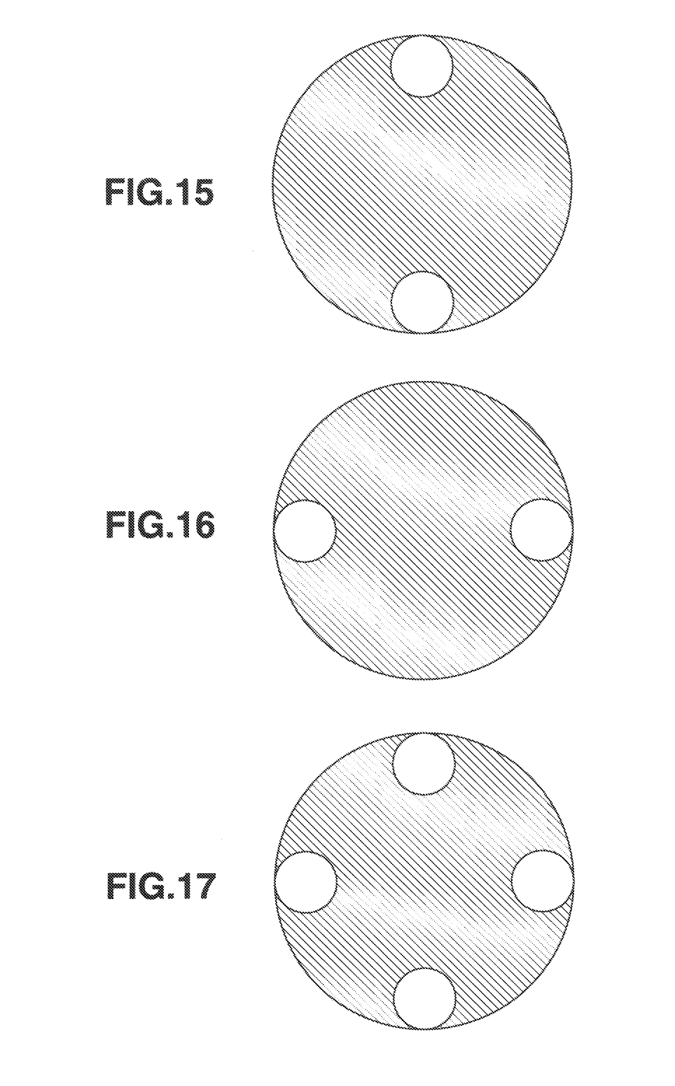

Method (iii) can achieve a further higher contrast than Methods (i) and (ii) by using dipole illumination with aperture configurations as shown in FIGS. 15 and 16, performing exposure to X and Y-direction line patterns in two separate steps, and overlaying the resulting optical images. The contrast may be enhanced by combining dipole illumination with s-polarized illumination.

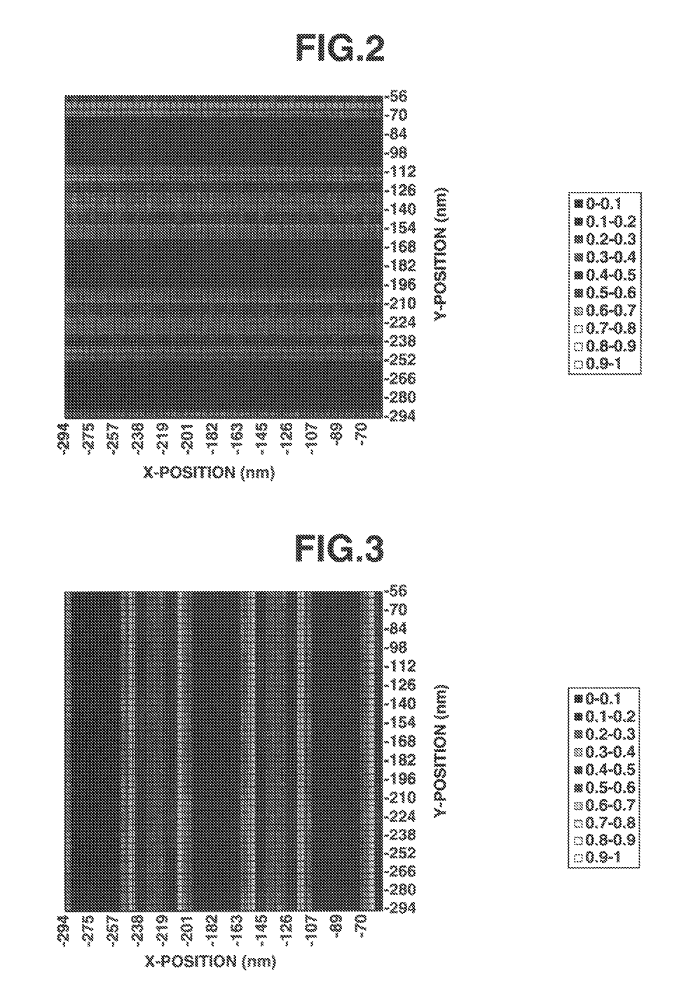

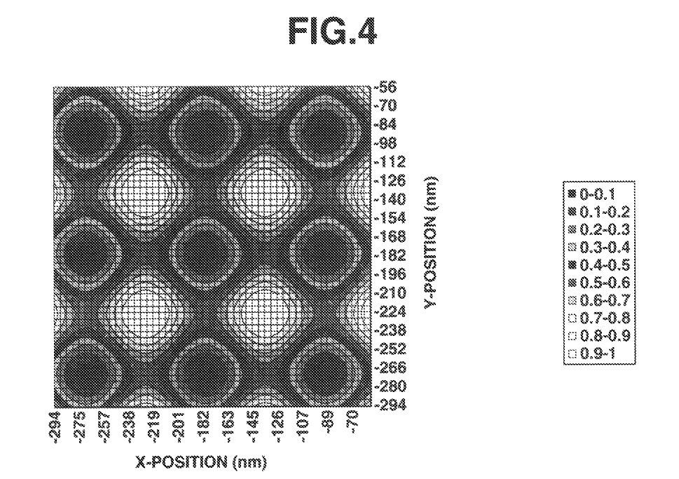

FIG. 2 is an optical image of X-direction lines having a pitch of 90 nm and a line size of 45 nm printed under conditions: ArF excimer laser of wavelength 193 nm, NA 1.3 lens, dipole illumination, 6% halftone phase shift mask, and s-polarization. FIG. 3 is an optical image of Y-direction lines having a pitch of 90 nm and a line size of 45 nm printed under conditions: ArF excimer laser of wavelength 193 nm, NA 1.3 lens, dipole illumination, 6% halftone phase shift mask, and s-polarization. A black area is a light shielded area while a white area is a high light intensity area. A definite contrast difference is recognized between white and black, indicating the presence of a fully light shielded area. FIG. 4 shows a contrast image obtained by overlaying the optical image of X-direction lines in FIG. 2 with that of Y-direction lines in FIG. 3. Against the expectation that a combination of X and Y lines may form a lattice-like image, weak light black areas draw circular shapes. As the pattern (circle) size becomes larger, the circular shape changes to a rhombic shape to merge with adjacent ones. As the circle size becomes smaller, circularity is improved, which is evidenced by the presence of a fully light shielded small circle.

Since Method (iii) involving double exposures provides a high optical contrast despite a reduced throughput as compared with Methods (i) and (ii) involving a single exposure, Method (iii) can form a fine pattern with dimensional uniformity and is advantageous for pitch narrowing. The angle between the first and second lines is preferably right, but may deviate from 90°, and the size and/or pitch may be the same or different between the first lines and the second lines. If a single mask bearing first lines in one area and second lines in another area is used, it is possible to carry out first and second exposures continuously. Two consecutive exposures using a single mask with the X and Y-direction contrasts emphasized can be carried out on the currently commercially available scanner.

It is difficult to form a fine hole pattern that holes are randomly arrayed at varying pitch and position. The super-resolution technology using off-axis illumination (such as dipole or cross-pole illumination) in combination with a phase shift mask and polarization is successful in improving the contrast of dense (or grouped) patterns, but not so the contrast of isolated patterns.

When the super-resolution technology is applied to repeating dense patterns, the pattern density bias between dense and isolated patterns, known as proximity bias, becomes a problem. As the super-resolution technology used becomes stronger, the resolution of a dense pattern is more improved, but the resolution of an isolated pattern remains unchanged. Then the proximity bias is exaggerated. In particular, an increase of proximity bias in a hole pattern resulting from further miniaturization poses a serious problem. One common approach taken to suppress the proximity bias is by biasing the size of a mask pattern. Since the proximity bias varies with properties of a resist composition, specifically dissolution contrast and acid diffusion, the proximity bias of a mask varies with the type of resist composition. For a particular type of resist composition, a mask having a different proximity bias must be used. This adds to the burden of mask manufacturing.

Then the pack and unpack (PAU) method is proposed in Proc. SPIE Vol. 5753, p 171 (2005), which involves strong super-resolution illumination of a first positive resist to resolve a dense hole pattern, coating the first positive resist pattern with a negative resist film material in alcohol solvent which does not dissolve the first positive resist pattern, exposure and development of an unnecessary hole portion to close the corresponding holes, thereby forming both a dense pattern and an isolated pattern. One problem of the PAU method is misalignment between first and second exposures, as the authors point out in the report. The hole pattern which is not closed by the second development experiences two developments and thus undergoes a size change, which is another problem.

To form a random pitch hole pattern by positive/negative reversal, a mask is used in which a lattice-like light-shielding pattern is arrayed over the entire surface and the width of gratings is thickened only where holes are to be formed.

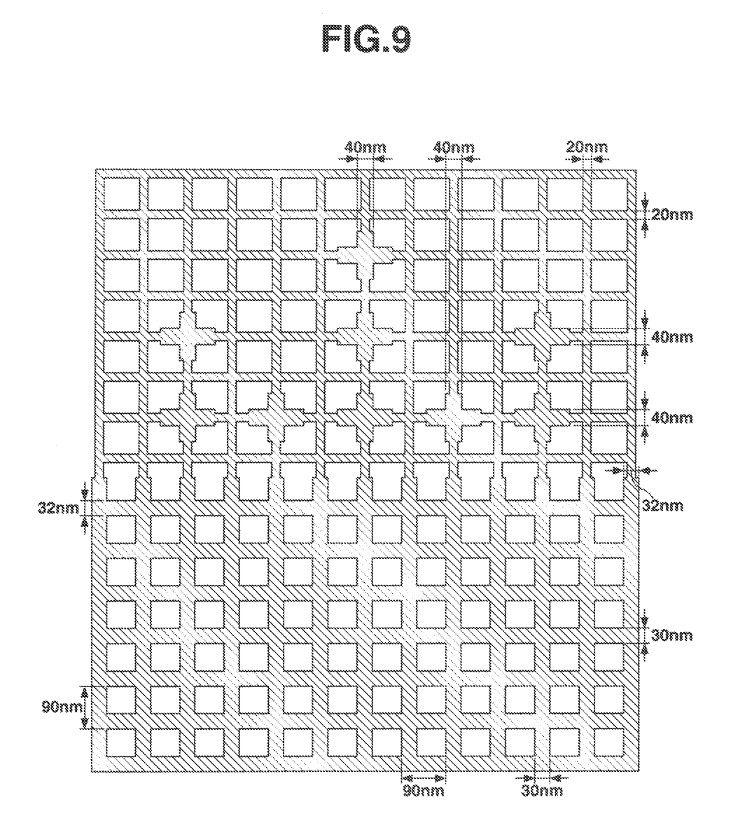

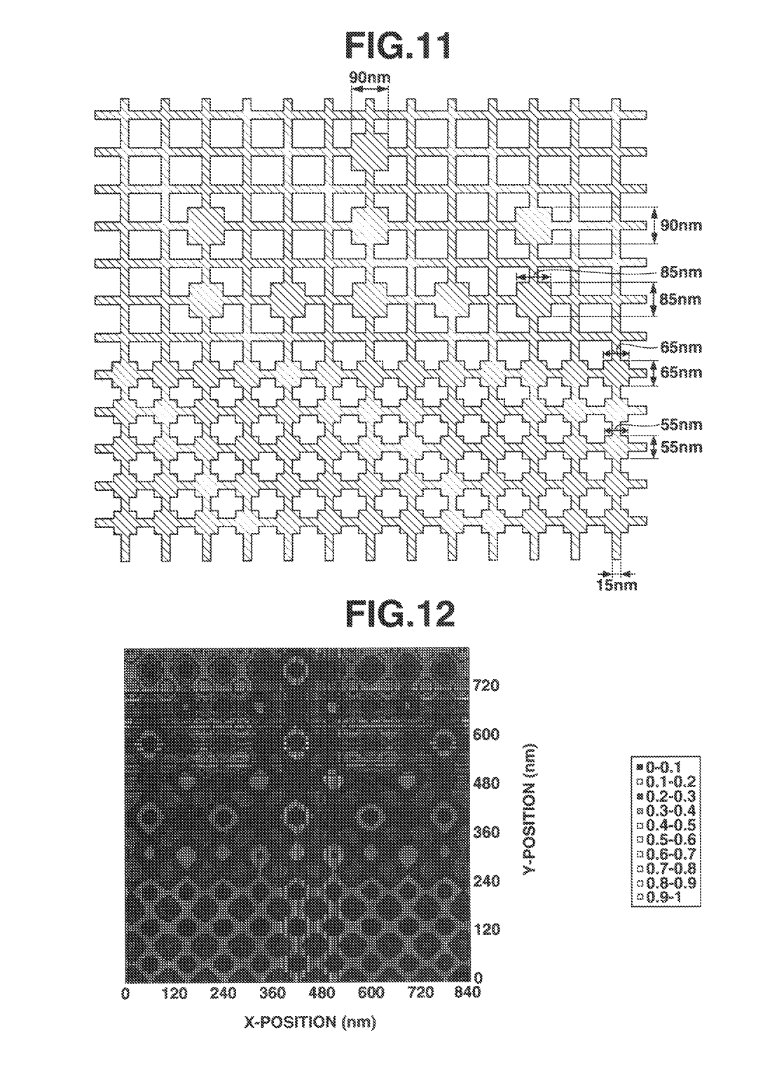

In Method (ii), a pattern of holes at random pitches can be formed by using a phase shift mask including a lattice-like first shifter having a line width equal to or less than a half pitch and a second shifter arrayed on the first shifter and consisting of lines whose on-wafer size is 2 to 30 nm thicker than the line width of the first shifter as shown in FIG. 9, whereby a pattern of holes is formed only where the thick shifter is arrayed. Alternatively, a pattern of holes at random pitches can be formed by using a phase shift mask including a lattice-like first shifter having a line width equal to or less than a half pitch and a second shifter arrayed on the first shifter and consisting of dots whose on-wafer size is 2 to 100 nm thicker than the line width of the first shifter as shown in FIG. 11, whereby a pattern of holes is formed only where the thick shifter is arrayed.

As shown in FIG. 9, on a lattice-like pattern having a pitch of 90 nm and a line width of 20 nm, thick crisscross or intersecting line segments are disposed where dots are to be formed. A black area corresponds to the halftone shifter portion. Line segments with a width of 30 nm are disposed in the dense pattern portion whereas thicker line segments (width 40 nm in FIG. 9) are disposed in more isolated pattern portions. Since the isolated pattern provides light with a lower intensity than the dense pattern, thicker line segments are used. Since the peripheral area of the dense pattern provides light with a relatively low intensity, line segments having a width of 32 nm are assigned to the peripheral area which width is slightly greater than that in the internal area of the dense pattern.

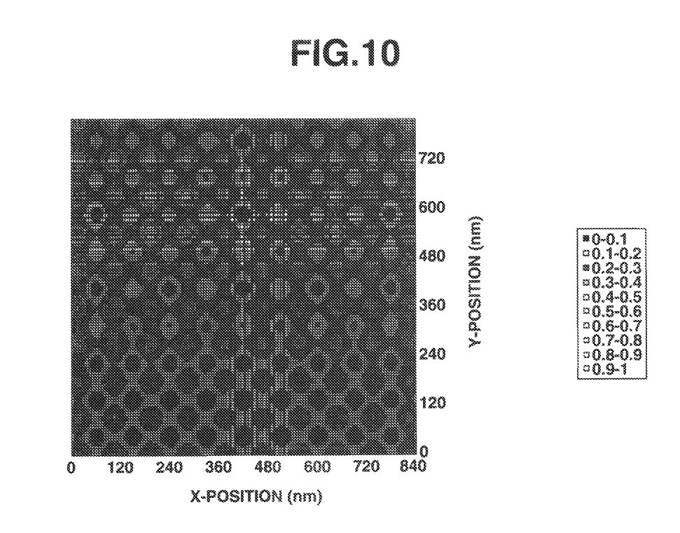

FIG. 10 shows an optical image from the mask of FIG. 9, indicating the contrast thereof. Black or light-shielded areas are where holes are formed via positive/negative reversal. Black spots are found at positions other than where holes are formed, but few are transferred in practice because they are of small size. Optimization such as reduction of the width of grating lines corresponding to unnecessary holes can inhibit transfer of unnecessary holes.

Also useful is a mask in which a lattice-like light-shielding pattern is arrayed over the entire surface and thick dots are disposed only where holes are to be formed. As shown in FIG. 11, on a lattice-like pattern having a pitch of 90 nm and a line width of 15 nm, thick dots are disposed where dots are to be formed. A black area corresponds to the halftone shifter portion. Square dots having one side with a size of 55 nm are disposed in the dense pattern portion whereas larger square dots (side size 90 nm in FIG. 11) are disposed in more isolated pattern portions. Although square dots are shown in the figure, the dots may have any shape including rectangular, rhombic, pentagonal, hexagonal, heptagonal, octagonal, and polygonal shapes and even circular shape. FIG. 12 shows an optical image from the mask of FIG. 11, indicating the contrast thereof. The presence of black or light-shielded spots substantially equivalent to those of FIG. 10 indicates that holes are formed via positive/negative reversal.

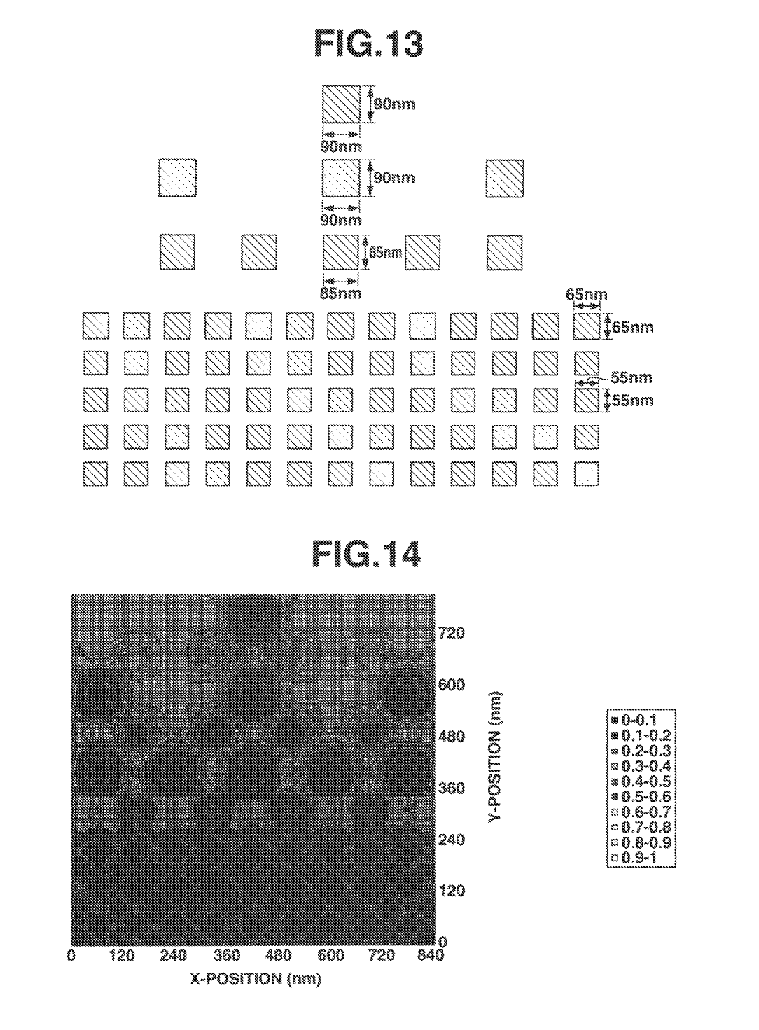

On use of a mask bearing no lattice-like pattern arrayed as shown in FIG. 13, black or light-shielded spots do not appear as shown in FIG. 14. In this case, holes are difficult to form, or even if holes are formed, a variation of mask size is largely reflected by a variation of hole size because the optical image has a low contrast.

### Example

Examples of the invention are given below by way of illustration and not by way of limitation. The abbreviation “pbw” is parts by weight. For all polymers, Mw and Mn are determined by GPC versus polystyrene standards using tetrahydrofuran solvent.

### Preparation of Resist Composition

A resist solution (Resist-1 to 32) was prepared by dissolving components in a solvent in accordance with the recipe shown in Table 1, and filtering through a Teflon® filter with a pore size of 0.2 μm. A comparative resist solution (Resist-33 to 41) was similarly prepared in accordance with the recipe shown in Table 2.

The polymers as base resin in Tables 1 and 2 have a structure, molecular weight (Mw) and dispersity (Mw/Mn) as shown in Tables 3 to 6. In Tables 3 to 6, the value in parentheses indicates a constitutional ratio (mol %) of the relevant recurring unit.

The polymeric additives in Tables 1 and 2 have a structure, molecular weight (Mw) and dispersity (Mw/Mn) as shown in Tables 7 to 10. In Tables 7 to 10, the value in parentheses indicates a constitutional ratio (mol %) of the relevant recurring unit.

The structure of photoacid generators in Tables 1 and 2 is shown in Table 11. The structure of quenchers in Tables 1 and 2 is shown in Table 12.

TABLE 1

| | | Polymeric | | | |
|---|---|---|---|---|---|
| | Base resin | additive | PAG | Quencher | Solvent |
| | (pbw) | (pbw) | (pbw) | (pbw) | (pbw) |
| Resist 1 | Polymer 1 (95) | PA-4 (5) | PAG-1 (8.7) | Q-1 (1.5) | PGMEA (2,100) |
| | | | | | CyHO (900) |
| Resist 2 | Polymer 2 (90) | PA-5 (10) | PAG-2 (10.2) | Q-1 (1.5) | PGMEA (2,100) |
| | | | | | CyHO (900) |
| Resist 3 | Polymer 3 (97) | PA-4 (3) | PAG-2 (10.2) | Q-2 (1.7) | PGMEA (2,100) |
| | | | | | CyHO (900) |
| Resist 4 | Polymer 4 (95) | PA-4 (5) | PAG-3 (9.3) | Q-2 (1.7) | PGMEA (2,100) |
| | | | | | CyHO (900) |
| Resist 5 | Polymer 5 (95) | PA-5 (5) | PAG-2 (5.1) | Q-6 (3.8) | PGMEA (2,700) |
| | | | | | GBL (300) |
| Resist 6 | Polymer 6 (95) | PA-4 (5) | PAG-2 (10.2) | Q-3 (2.9) | PGMEA (2,100) |
| | | | | | CyHO (900) |
| Resist 7 | Polymer 7 (95) | PA-4 (5) | PAG-2 (5.1) | Q-6 (3.8) | PGMEA (2,700) |
| | | | | | GBL (300) |
| Resist 8 | Polymer 8 (95) | PA-4 (5) | PAG-4 (5.5) | Q-5 (3.4) | PGMEA (2,700) |
| | | | | | GBL (300) |
| Resist 9 | Polymer 9 (95) | PA-4 (5) | PAG-2 (10.2) | Q-5 (3.4) | PGMEA (2,700) |
| | | | | | GBL (300) |
| Resist 10 | Polymer 10 (95) | PA-5 (5) | PAG-2 (10.2) | Q-4 (2.8) | PGMEA (2,100) |
| | | | | | CyHO (900) |
| Resist 11 | Polymer 11 (95) | PA-5 (5) | PAG-2 (10.2) | Q-2 (1.7) | PGMEA (2,100) |
| | | | | | CyHO (900) |
| Resist 12 | Polymer 12 (95) | PA-4 (5) | PAG-2 (10.2) | Q-2 (1.7) | PGMEA (2,100) |
| | | | | | CyHO (900) |
| Resist 13 | Polymer 13 (95) | PA-4 (5) | PAG-2 (5.1) | Q-5 (3.4) | PGMEA (2,700) |
| | | | | | GBL (300) |
| Resist 14 | Polymer 14 (85) | PA-5 (15) | PAG-2 (6.1) | Q-6 (2.6) | PGMEA (2,700) |
| | | | | Q-1 (0.5) | GBL (300) |
| Resist 15 | Polymer 15 (90) | PA-5 (10) | PAG-2 (6.1) | Q-6 (2.6) | PGMEA (2,700) |
| | | | | Q-2 (0.8) | GBL (300) |
| Resist 16 | Polymer 16 (95) | PA-5 (5) | PAG-2 (5.1) | Q-5 (3.4) | PGMEA (2,700) |
| | | | | | GBL (300) |
| Resist 17 | Polymer 17 (95) | PA-5 (5) | PAG-2 (10.2) | Q-2 (1.7) | PGMEA (2,100) |
| | | | | | CyHO (900) |
| Resist 18 | Polymer 18 (95) | PA-5 (5) | PAG-2 (5.1) | Q-5 (3.4) | PGMEA (2,700) |
| | | | | | GBL (300) |
| Resist 19 | Polymer 3 (95) | PA-1 (5) | PAG-2 (10.2) | Q-2 (1.7) | PGMEA (2,100) |
| | | | | | CyHO (900) |
| Resist 20 | Polymer 3 (95) | PA-2 (5) | PAG-2 (10.2) | Q-2 (1.7) | PGMEA (2,100) |
| | | | | | CyHO (900) |
| Resist 21 | Polymer 3 (95) | PA-3 (5) | PAG-2 (10.2) | Q-3 (2.9) | PGMEA (2,100) |
| | | | | | CyHO (900) |
| Resist 22 | Polymer 3 (95) | PA-6 (5) | PAG-2 (10.2) | Q-3 (2.9) | PGMEA (2,100) |
| | | | | | CyHO (900) |
| Resist 23 | Polymer 6 (93) | PA-7 (7) | PAG-3 (4.6) | Q-5 (3.4) | PGMEA (2,700) |
| | | | | | GBL (300) |
| Resist 24 | Polymer 6 (90) | PA-8 (10) | PAG-4 (5.5) | Q-5 (3.4) | PGMEA (2,700) |
| | | | | | GBL (300) |
| Resist 25 | Polymer 6 (95) | PA-9 (5) | PAG-2 (10.2) | Q-3 (2.9) | PGMEA (2,100) |
| | | | | | CyHO (900) |
| Resist 26 | Polymer 14 (95) | PA-10 (5) | PAG-2 (10.2) | Q-3 (2.9) | PGMEA (2,100) |
| | | | | | CyHO (900) |
| Resist 27 | Polymer 14 (95) | PA-11 (5) | PAG-2 (10.2) | Q-3 (2.9) | PGMEA (2,100) |
| | | | | | CyHO (900) |
| Resist 28 | Polymer 14 (95) | PA-12 (5) | PAG-2 (10.2) | Q-3 (2.9) | PGMEA (2,100) |
| | | | | | CyHO (900) |
| Resist 29 | Polymer 14 (95) | PA-13 (5) | PAG-2 (10.2) | Q-3 (2.9) | PGMEA (2,100) |
| | | | | | CyHO (900) |
| Resist 30 | Polymer 14 (95) | PA-14 (5) | PAG-2 (10.2) | Q-3 (2.9) | PGMEA (2,100) |
| | | | | | CyHO (900) |
| Resist 31 | Polymer 1 (45) | PA-5 (10) | PAG-2 (10.2) | Q-3 (2.9) | PGMEA (2,100) |
| | Polymer 19 (45) | | | | CyHO (900) |
| Resist 32 | Polymer 3 (95) | PA-1 (5) | PAG-2 (10.2) | Q-3 (2.9) | PGMEA (2,100) |
| | | PA-4 (5) | | | CyHO (900) |

TABLE 2

| | | Polymeric | | | |
|---|---|---|---|---|---|
| | Base resin | additive | PAG | Quencher | Solvent |
| | (pbw) | (pbw) | (pbw) | (pbw) | (pbw) |
| Resist 33 | Polymer 19 (95) | PA-4 (5) | PAG-2 (10.2) | Q-2 (1.7) | PGMEA (2,100) |
| | | | | | CyHO (900) |
| Resist 34 | Polymer 19 (95) | PA-5 (5) | PAG-2 (10.2) | Q-4 (2.8) | PGMEA (2,100) |
| | | | | | CyHO (900) |
| Resist 35 | Polymer 20 (95) | PA-4 (5) | PAG-2 (10.2) | Q-3 (2.9) | PGMEA (2,100) |
| | | | | | CyHO (900) |
| Resist 36 | Polymer 20 (95) | PA-7 (5) | PAG-2 (5.1) | Q-2 (1.7) | PGMEA (2,100) |
| | | | | | CyHO (900) |
| Resist 37 | Polymer 3 (95) | PA-15 (5) | PAG-2 (10.2) | Q-2 (1.7) | PGMEA (2,100) |
| | | | | | CyHO (900) |
| Resist 38 | Polymer 6 (95) | PA-15 (5) | PAG-3 (4.6) | Q-5 (3.4) | PGMEA (2,700) |
| | | | | | GBL (300) |
| Resist 39 | Polymer 3 (95) | PA-16 (5) | PAG-2 (10.2) | Q-3 (2.9) | PGMEA (2,100) |
| | | | | | CyHO (900) |
| Resist 40 | Polymer 14 (95) | PA-16 (5) | PAG-2 (10.2) | Q-3 (2.9) | PGMEA (2,100) |
| | | | | | CyHO (900) |
| Resist 41 | Polymer 3 (100) | - (0) | PAG-2 (10.2) | Q-3 (2.9) | PGMEA (2,100) |
| | | | | | CyHO (900) |

TABLE 3

| | Constitutional units | | | | | |
|---|---|---|---|---|---|---|
| | Unit 1 | Unit 2 | Unit 3 | Unit 4 | Mw | Mw/Mn |
| Polymer 1 | 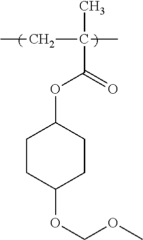 (50) | 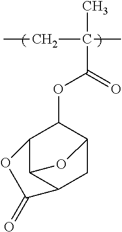 (50) | | | 7,200 | 1.6 |
| Polymer 2 | 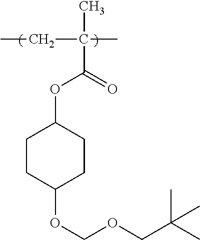 (50) | 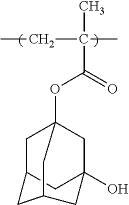 (10) | 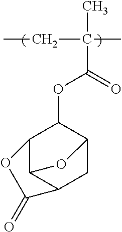 (40) | | 6,900 | 1.8 |
| Polymer 3 | 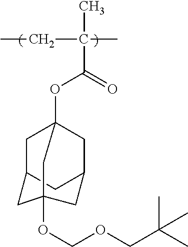 (50) | 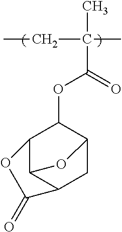 (30) | 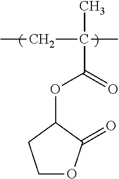 (20) | | 6,300 | 1.8 |
| Polymer 4 | 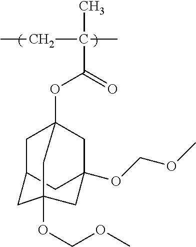 (40) | 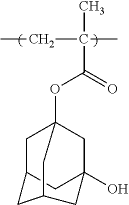 (10) | 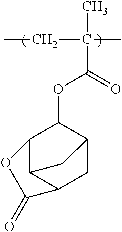 (20) | 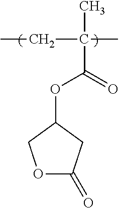 (30) | 7,400 | 1.7 |
| Polymer 5 | 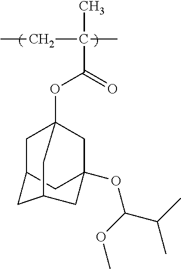 (35) | 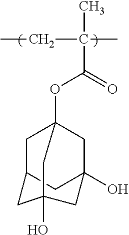 (15) | 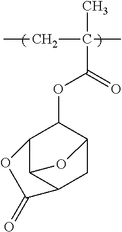 (50) | | 8,200 | 1.6 |

TABLE 4

| | Constitutional units | | | | | |
|---|---|---|---|---|---|---|
| | Unit 1 | Unit 2 | Unit 3 | Unit 4 | Mw | Mw/Mn |
| Polymer 6 | 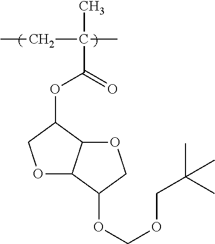 (45) | 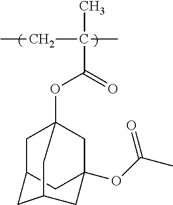 (15) | 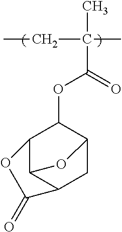 (40) | | 7,500 | 1.8 |
| Polymer 7 | 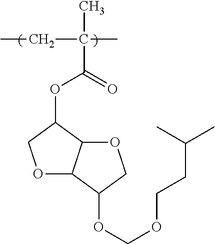 (60) | 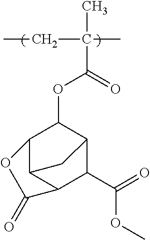 (20) | 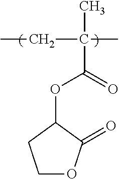 (20) | | 7,600 | 1.6 |
| Polymer 8 | 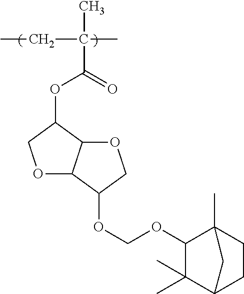 (40) | 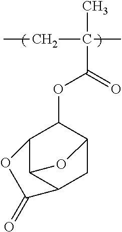 (15) | 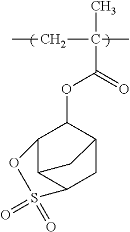 (45) | | 9,100 | 1.9 |
| Polymer 9 | 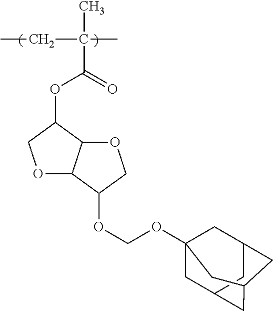 (50) | 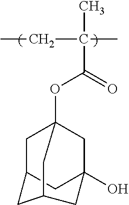 (10) | 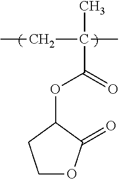 (20) | 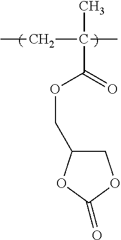 (20) | 8,700 | 1.7 |
| Polymer 10 | 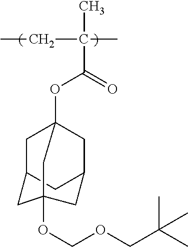 (50) | 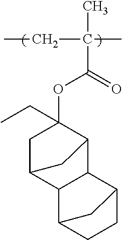 (10) | 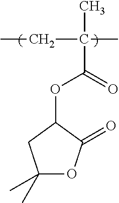 (40) | | 8,100 | 1.8 |

TABLE 5

| | Constitutional units | | | | | Mw/ |
|---|---|---|---|---|---|---|
| | Unit 1 | Unit 2 | Unit 3 | Unit 4 | Mw | Mn |
| Polymer 11 | 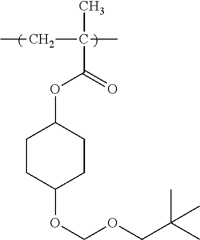 (30) | 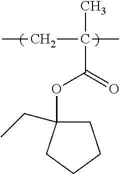 (20) | 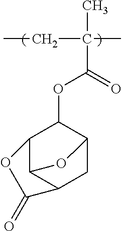 (45) | 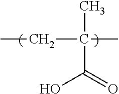 (5) | 7,200 | 1.7 |
| Polymer 12 | 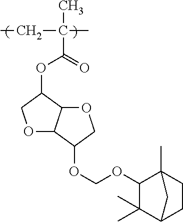 (30) | 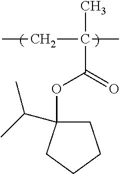 (30) | 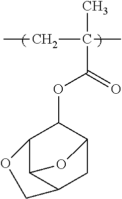 (30) | 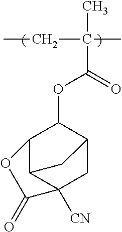 (10) | 6,400 | 2.0 |
| Polymer 13 | 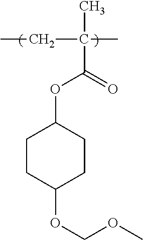 (40) | 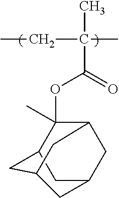 (10) | 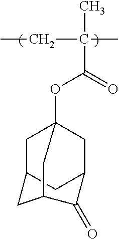 (15) | 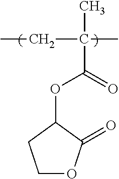 (35) | 7,700 | 1.9 |
| Polymer 14 | 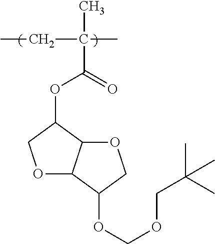 (40) | 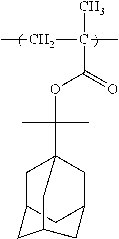 (10) | 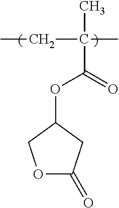 (30) | 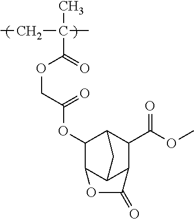 (20) | 8,000 | 1.8 |
| Polymer 15 | 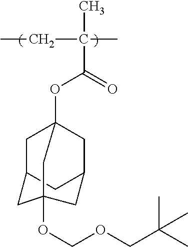 (20) | 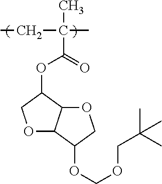 (30) | 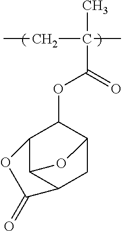 (50) | | 5,900 | 2.0 |

TABLE 6

| | Constitutional units | | | | | Mw/ |
|---|---|---|---|---|---|---|
| | Unit 1 | Unit 2 | Unit 3 | Unit 4 | Mw | Mn |
| Polymer 16 | 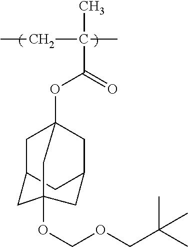 (40) | 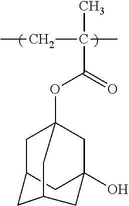 (20) | 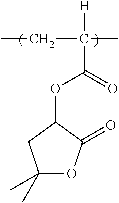 (40) | | 7,800 | 1.8 |
| Polymer 17 | 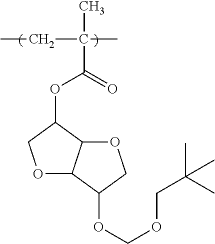 (47) | 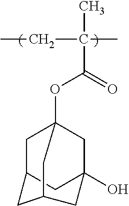 (10) | 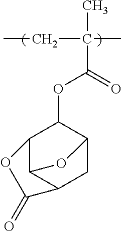 (40) | 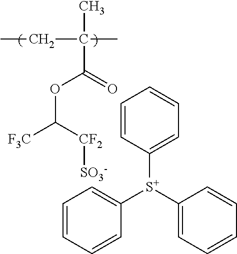 (3) | 9,100 | 1.8 |
| Polymer 18 | 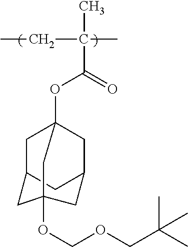 (28) | 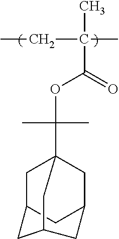 (30) | 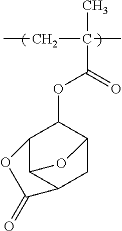 (40) | 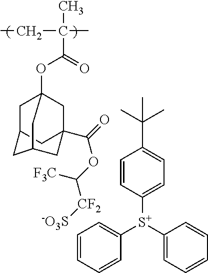 (2) | 8,000 | 1.7 |
| Polymer 19 | 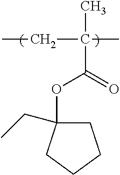 (50) | 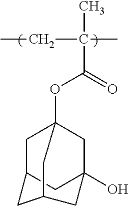 (10) | 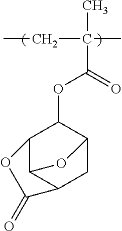 (40) | | 7,300 | 1.8 |
| Polymer 20 | 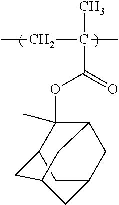 (50) | 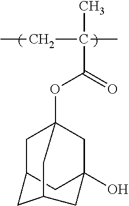 (10) | 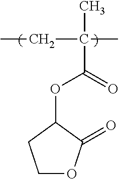 (40) | | 6,600 | 1.7 |

TABLE 7

| | Constitutional units | | | | |
|---|---|---|---|---|---|
| | Unit 1 | Unit 2 | Unit 3 | Mw | Mw/Mn |
| PA-1 | 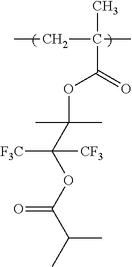 (100) | | | 7,400 | 1.7 |
| PA-2 | 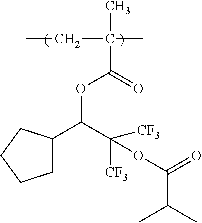 (100) | | | 6,700 | 1.6 |
| PA-3 | 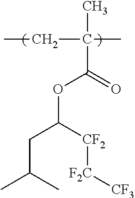 (100) | | | 6,900 | 1.8 |
| PA-4 | 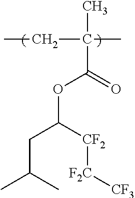 (50) | 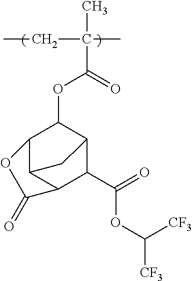 (50) | | 7,500 | 1.9 |

TABLE 8

| | Constitutional units | | | | |
|---|---|---|---|---|---|
| | Unit 1 | Unit 2 | Unit 3 | Mw | Mw/Mn |
| PA-5 | 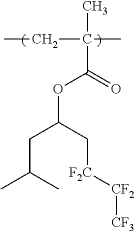 (40) | 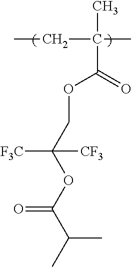 (30) | 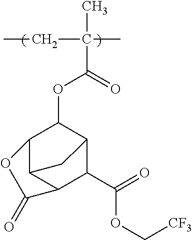 (30) | 5,800 | 1.6 |
| PA-6 | 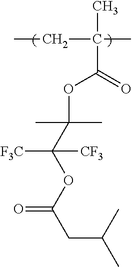 (50) | 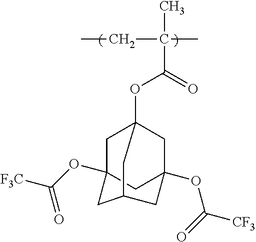 (50) | | 9,800 | 2.0 |
| PA-7 | 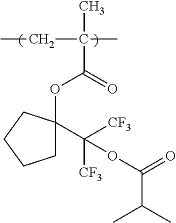 (60) | 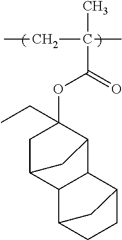 (40) | | 6,100 | 1.6 |
| PA-8 | 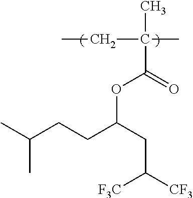 (40) | 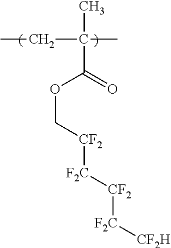 (30) | 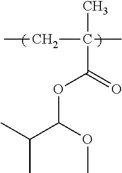 (30) | 9,300 | 2.0 |

TABLE 9

| | Constitutional units | | | | |
|---|---|---|---|---|---|
| | Unit 1 | Unit 2 | Unit 3 | Mw | Mw/Mn |
| PA-9 | 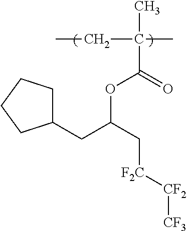 (70) | 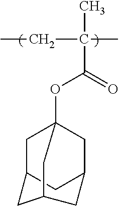 (30) | | 6,500 | 2.1 |
| PA-10 | 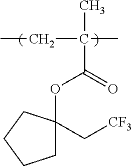 (30) | 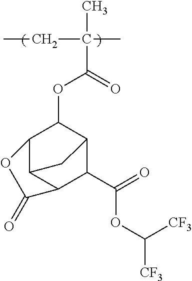 (20) | 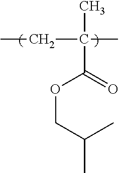 (50) | 8,100 | 1.8 |
| PA-11 | 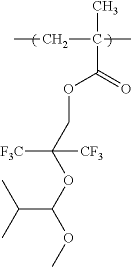 (50) | 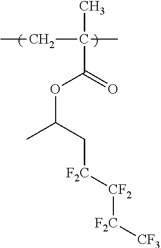 (40) | 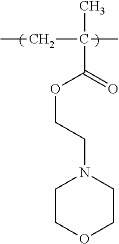 (10) | 7,200 | 1.7 |
| PA-12 | 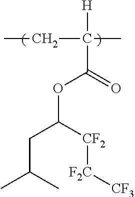 (50) | 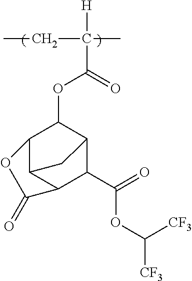 (50) | | 6,400 | 2.0 |

TABLE 10

| | Constitutional units | | | | |
|---|---|---|---|---|---|
| | Unit 1 | Unit 2 | Unit 3 | Mw | Mw/Mn |
| PA-13 | 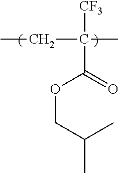 (50) | 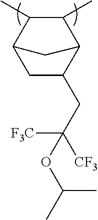 (50) | | 6,700 | 2.1 |
| PA-14 | 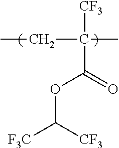 (50) | 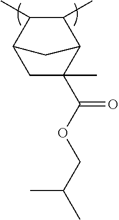 (50) | | 6,900 | 2.0 |
| PA-15 | 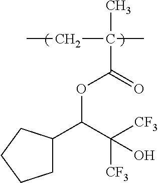 (100) | | | 5,800 | 1.9 |
| PA-16 | 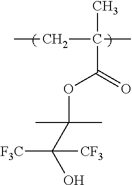 (50) | 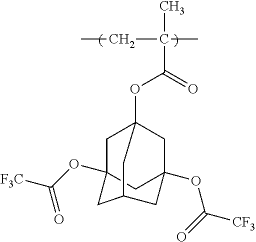 (50) | | 9,200 | 1.7 |

TABLE 11

| | |
|---|---|
| 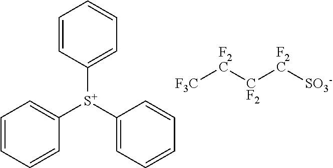 | PAG-1 |
| 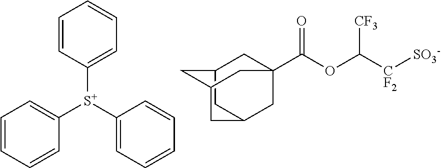 | PAG-2 |
| 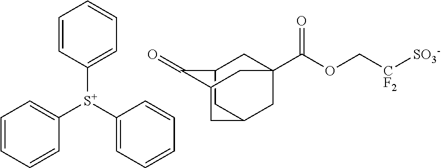 | PAG-3 |
| 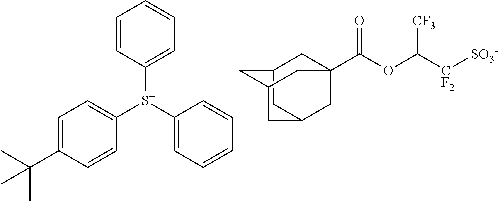 | PAG-4 |

TABLE 12

| | |
|---|---|
| 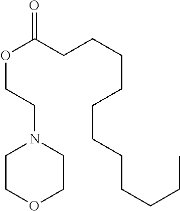 [SMILES: CCCCCCCCCCCC(=O)OCCN1CCOCC1] | Q-1 |
| 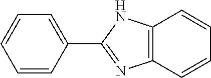 [SMILES: c1ccc(-c2nc3ccccc3[nH]2)cc1] | Q-2 |
| 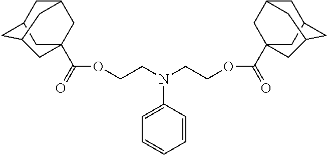 [SMILES: O=C(OCCN(CCOC(=O)C12CC3CC(CC(C3)C1)C2)c1ccccc1)C12CC3CC(CC(C3)C1)C2] | Q-3 |
| 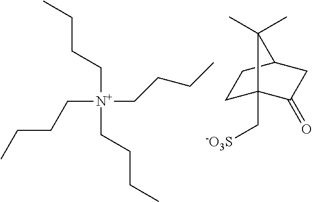 | Q-4 |
| 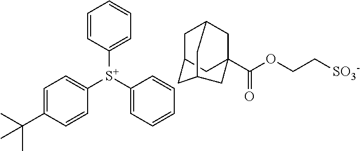 | Q-5 |
| 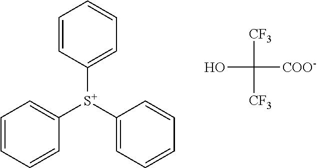 | Q-6 |

The organic solvents in Tables 1 and 2 are as follows.

PGMEA: propylene glycol monomethyl ether acetate

CyHO: cyclohexanone

GBL: γ-butyrolactone

All the resist compositions in Tables 1 and 2 contained 0.1 pbw of surfactant A.
Surfactant A: 3-methyl-3-(2,2,2-trifluoroethoxymethyl)-oxetane/tetrahydrofuran/2,2-dimethyl-1,3-propanediol copolymer of the formula below (Omnova Solutions, Inc.)

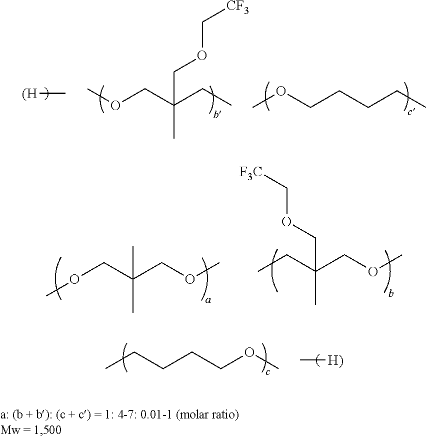

### Examples 1 to 32 & Comparative Examples 1 to 9

### Evaluation Method

A trilayer process substrate was prepared by forming a spin-on carbon film (ODL-50 by Shin-Etsu Chemical Co., Ltd., carbon content 80 wt %) of 200 nm thick on a silicon wafer and forming a silicon-containing spin-on hard mask (SHB-A940 by Shin-Etsu Chemical Co., Ltd., silicon content 43 wt %) of 35 nm thick thereon. The resist solution (in Tables 1 and 2) was spin coated on the trilayer process substrate, then baked (PAB) on a hot plate at 100° C. for 60 seconds to form a resist film of 90 nm thick.

Using an ArF excimer laser immersion lithography scanner (NSR-610C by Nikon Corp., NA 1.30, σ0.98/0.74, dipole opening 90 deg., s-polarized illumination), exposure was carried out in a varying exposure dose. After exposure, the resist film was baked (PEB) at an arbitrary temperature for 60 seconds and then developed in an arbitrary developer (DS-1 to 3) for 30 seconds. The wafer was then rinsed with diisoamyl ether.

The developers DS-1, 2 and 3 are identified below.
DS-1: butyl acetate
DS-2: 2-heptane
DS-3: mixture of 1/1 (weight ratio) butyl acetate/methyl benzoate

The mask used herein is a binary mask having an on-mask design corresponding to a 45-nm line/90-nm pitch pattern (actual on-mask size is 4 times because of ¼ image reduction projection exposure). A line pattern formed in the light-transmissive region was observed under an electron microscope. The optimum dose (Eop) was a dose (mJ/cm²) that provided a line width of 45 nm. The cross-sectional profile of the pattern at the optimum dose was observed under an electron microscope and judged passed or rejected according to the following criterion.
Passed: pattern of perpendicular sidewall; acceptable profile
Rejected: T-top profile with surface layer substantially clogged or inversely tapered profile of pattern with graded sidewall (greater line width nearer to surface layer); unacceptable profile

The collapse limit was a minimum width (nm) of lines which could be resolved without collapse when the line width was reduced by increasing the exposure dose. A smaller value indicates better collapse resistance.

Similarly, the resist composition was coated and baked to form a resist film on a wafer. A contact angle with water of the resist film was measured, using an inclination contact angle meter Drop Master 500 by Kyowa Interface Science Co., Ltd. Specifically, the wafer covered with the resist film was kept horizontal, and 50 μL of pure water was dropped on the resist film to form a droplet. While the wafer was gradually inclined, the receding contact angle at the time when the droplet started sliding down was determined. A greater receding contact angle is preferred because less water droplets are left on the resist film surface even when the scanning rate of immersion lithography is increased.

### Evaluation Results

The test results of the resist compositions in Table 1 are shown in Table 13 together with the conditions (PEB temperature and developer) under which the resist compositions in Table 1 are evaluated. The test results of the comparative resist compositions in Table 2 are shown in Table 14 together with the conditions (PEB temperature and developer) under which the comparative resist compositions in Table 2 are evaluated.

TABLE 13

| | | | | | | | | Receding |
|---|---|---|---|---|---|---|---|---|
| | | | PEB | | | | Collapse | contact |
| | | Resist | temp. | | Eop | | limit | angle |
| | | composition | (° C.) | Developer | (mJ/cm²) | Profile | (nm) | (°) |
| Example | 1 | Resist 1 | 100 | DS-1 | 43 | Passed | 32 | 82 |
| | 2 | Resist 2 | 95 | DS-2 | 40 | Passed | 31 | 83 |
| | 3 | Resist 3 | 90 | DS-3 | 47 | Passed | 29 | 81 |
| | 4 | Resist 4 | 90 | DS-1 | 48 | Passed | 30 | 82 |
| | 5 | Resist 5 | 85 | DS-1 | 38 | Passed | 36 | 82 |
| | 6 | Resist 6 | 95 | DS-1 | 44 | Passed | 30 | 82 |
| | 7 | Resist 7 | 85 | DS-1 | 42 | Passed | 36 | 83 |
| | 8 | Resist 8 | 100 | DS-1 | 43 | Passed | 34 | 82 |
| | 9 | Resist 9 | 90 | DS-1 | 45 | Passed | 35 | 82 |
| | 10 | Resist 10 | 90 | DS-1 | 40 | Passed | 32 | 82 |
| | 11 | Resist 11 | 100 | DS-1 | 39 | Passed | 30 | 81 |
| | 12 | Resist 12 | 90 | DS-1 | 40 | Passed | 31 | 82 |
| | 13 | Resist 13 | 105 | DS-1 | 42 | Passed | 35 | 81 |
| | 14 | Resist 14 | 100 | DS-1 | 42 | Passed | 33 | 83 |
| | 15 | Resist 15 | 90 | DS-1 | 43 | Passed | 32 | 82 |
| | 16 | Resist 16 | 90 | DS-1 | 45 | Passed | 34 | 82 |
| | 17 | Resist 17 | 90 | DS-1 | 42 | Passed | 32 | 83 |
| | 18 | Resist 18 | 100 | DS-1 | 43 | Passed | 31 | 82 |
| | 19 | Resist 19 | 90 | DS-1 | 46 | Passed | 31 | 86 |
| | 20 | Resist 20 | 90 | DS-1 | 50 | Passed | 31 | 84 |
| | 21 | Resist 21 | 90 | DS-1 | 48 | Passed | 30 | 86 |
| | 22 | Resist 22 | 90 | DS-1 | 46 | Passed | 28 | 88 |
| | 23 | Resist 23 | 95 | DS-1 | 42 | Passed | 36 | 83 |
| | 24 | Resist 24 | 95 | DS-1 | 44 | Passed | 36 | 86 |
| | 25 | Resist 25 | 95 | DS-1 | 43 | Passed | 29 | 83 |
| | 26 | Resist 26 | 100 | DS-1 | 42 | Passed | 30 | 82 |
| | 27 | Resist 27 | 100 | DS-1 | 41 | Passed | 33 | 80 |
| | 28 | Resist 28 | 100 | DS-1 | 42 | Passed | 32 | 81 |
| | 29 | Resist 29 | 100 | DS-1 | 44 | Passed | 32 | 86 |
| | 30 | Resist 30 | 100 | DS-1 | 43 | Passed | 31 | 85 |
| | 31 | Resist 31 | 100 | DS-1 | 45 | Passed | 33 | 83 |
| | 32 | Resist 32 | 100 | DS-1 | 48 | Passed | 31 | 84 |

TABLE 14

| | | | | | | | | Receding |
|---|---|---|---|---|---|---|---|---|
| | | | PEB | | | | Collapse | contact |
| | | Resist | temp. | | Eop | | limit | angle |
| | | composition | (° C.) | Developer | (mJ/cm²) | Profile | (nm) | (°) |
| Comparative | 1 | Resist 33 | 100 | DS-1 | 42 | Rejected | 42 | 81 |
| Example | 2 | Resist 34 | 100 | DS-2 | 44 | Rejected | 41 | 81 |
| | 3 | Resist 35 | 105 | DS-3 | 46 | Rejected | 42 | 82 |
| | 4 | Resist 36 | 105 | DS-1 | 45 | Rejected | 44 | 80 |
| | 5 | Resist 37 | 90 | DS-1 | 47 | Passed | 42 | 72 |
| | 6 | Resist 38 | 95 | DS-1 | 45 | Passed | 48 | 70 |
| | 7 | Resist 39 | 90 | DS-1 | 46 | Passed | 43 | 76 |
| | 8 | Resist 40 | 100 | DS-1 | 42 | Passed | 44 | 77 |
| | 9 | Resist 41 | 100 | DS-1 | 48 | Passed | 40 | 61 |

It is demonstrated that the resist compositions comprising a specific polymer in combination with a specific polymeric additive, when subjected to negative development in organic solvent, meet both satisfactory pattern profile and collapse resistance and exhibit a high receding contact angle compatible with the immersion lithography.

While the invention has been described with reference to a preferred embodiment, it will be understood by those skilled in the art that various changes may be made and equivalents may be substituted for elements thereof without departing from the scope of the invention. Therefore, it is intended that the invention not be limited to the particular embodiment disclosed as the best mode contemplated for carrying out this invention, but that the invention will include all embodiments falling within the scope of the appended claims.

Japanese Patent Application No. 2011-196667 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A pattern forming process comprising the steps of:
applying a resist composition onto a substrate, the resist composition comprising (A) a polymer comprising recurring units of the structure having a hydroxyl group protected with an acid labile group, (B) a photoacid generator, (C) an organic solvent, and (D) a polymeric additive comprising recurring units having at least one fluorine atom, the polymeric additive being free of hydroxyl,
prebaking the composition to form a resist film,
exposing the resist film to high-energy radiation,
baking, and
developing the exposed film in an organic solvent-based developer to selectively dissolve the unexposed region of resist film to form a negative pattern.

2. The process of claim 1 wherein the polymer comprising recurring units of the structure having a hydroxyl group protected with an acid labile group comprises recurring units having the general formula (1): 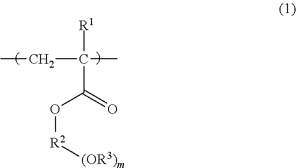
wherein R¹ is hydrogen or methyl, R² is a straight, branched or cyclic C₂-C₁₆ aliphatic hydrocarbon group having a valence of 2 to 5, which may contain an ether or ester bond, R³ is an acid labile group, and m is an integer of 1 to 4.

3. The process of claim 2 wherein the acid labile group R³ in recurring unit (1) has the general formula (2): 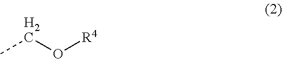
wherein the broken line denotes a valence bond and R⁴ is a monovalent, straight, branched or cyclic C₁-C₁₅ hydrocarbon group.

4. The process of claim 1 wherein the polymeric additive (D) comprising recurring units having at least one fluorine atom comprises recurring units of one or more type having the general formula (3): 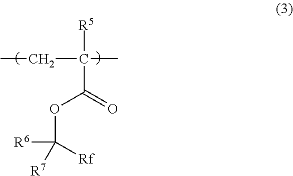
wherein R⁵ is hydrogen, methyl or trifluoromethyl, R⁶ and R⁷ are each independently hydrogen or a straight, branched or cyclic C₁-C₁₅ alkyl group, or R⁶ and R⁷ may bond together to form a ring with the carbon atom to which they are attached, and Rf is a straight or branched C₁-C₁₅ alkyl group in which at least one hydrogen atom is substituted by a fluorine atom.

5. The process of claim 1 wherein the developer comprises at least one organic solvent selected from the group consisting of 2-octanone, 2-nonanone, 2-heptanone, 3-heptanone, 4-heptanone, 2-hexanone, 3-hexanone, diisobutyl ketone, 2-methylcyclohexanone, 3-methylcyclohexanone, 4-methylcyclohexanone, acetophenone, 2′-methylacetophenone, 4′-methylacetophenone, propyl acetate, butyl acetate, isobutyl acetate, amyl acetate, isoamyl acetate, butenyl acetate, phenyl acetate, propyl formate, butyl formate, isobutyl formate, amyl formate, isoamyl formate, methyl valerate, methyl pentenoate, methyl crotonate, ethyl crotonate, methyl lactate, ethyl lactate, propyl lactate, butyl lactate, isobutyl lactate, amyl lactate, isoamyl lactate, methyl 2-hydroxyisobutyrate, ethyl 2-hydroxyisobutyrate, methyl benzoate, ethyl benzoate, benzyl acetate, methyl phenylacetate, benzyl formate, phenylethyl formate, methyl 3-phenylpropionate, benzyl propionate, ethyl phenylacetate, and 2-phenylethyl acetate, in a concentration of at least 60% by weight of the developer.

6. The process of claim 1 wherein the step of exposing the resist film to high-energy radiation includes ArF excimer laser immersion lithography of 193 nm wavelength or EUV lithography of 13.5 nm wavelength.

7. A resist composition comprising (A) a polymer comprising recurring units of the structure having a hydroxyl group protected with an acid labile group, (B) a photoacid generator, (C) an organic solvent, and (D) a polymeric additive comprising recurring units having at least one fluorine atom, the polymeric additive being free of hydroxyl, the polymeric additive being present in an amount of 1% to 30% by weight based on the total amount of all polymers.

8. The resist composition of claim 1 wherein the polymer comprising recurring units of the structure having a hydroxyl group protected with an acid labile group comprises recurring units having the general formula (1): 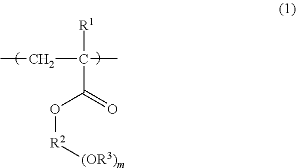
wherein R¹ is hydrogen or methyl, R² is a straight, branched or cyclic C₂-C₁₆ aliphatic hydrocarbon group having a valence of 2 to 5, which may contain an ether or ester bond, R³ is an acid labile group, and m is an integer of 1 to 4.

9. The resist composition of claim 8 wherein the acid labile group R³ in recurring unit (1) has the general formula (2): 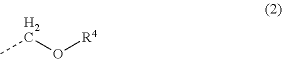
wherein the broken line denotes a valence bond and R⁴ is a monovalent, straight, branched or cyclic C₁-C₁₅ hydrocarbon group.

10. The resist composition of claim 7 wherein the polymeric additive (D) comprising recurring units having at least one fluorine atom comprises recurring units of one or more type having the general formula (3): 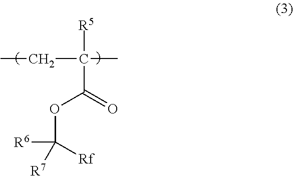
wherein R⁵ is hydrogen, methyl or trifluoromethyl, R⁶ and R⁷ are each independently hydrogen or a straight, branched or cyclic C₁-C₁₅ alkyl group, or R⁶ and R⁷ may bond together to form a ring with the carbon atom to which they are attached, and Rf is a straight or branched C₁-C₁₅ alkyl group in which at least one hydrogen atom is substituted by a fluorine atom.
